(19) United States
(12) Patent Application Publication
(10) Pub. No.: US 2025/0153261 A1
(43) Pub. Date: May 15, 2025

(54) TECHNIQUES FOR SEAM LOCALIZATION AND GAP MEASUREMENT

(71) Applicant: Path Robotics, Inc., Columbus, OH (US)

(72) Inventors: Madhavun Candadai VASU, Westerville, OH (US); Siqi HUANG, Dublin, OH (US); Amrish BASKARAN, Columbus, OH (US); Colin BUNKER, Columbus, OH (US); Alexander James LONSBERRY, Gahanna, OH (US)

(21) Appl. No.: 18/506,113

(22) Filed: Nov. 9, 2023

(51) Int. Cl. B23K 9/095; B25J 9/16; B25J 11/00; B25J 19/02; G06F 30/10; G06T 7/00; G06T 7/70; G06V 10/141

(52) U.S. Cl. CPC B23K 9/0953; B23K 9/0956; B25J 9/1682; B25J 11/005; B25J 19/023; G06F 30/10; G06T 7/0008; G06T 7/70; G06V 10/141; G06T 2200/04; G06T 2207/10012; G06T 2207/30152; G06T 2207/30164; G06V 2201/121

(57) ABSTRACT

This disclosure provides systems, methods, and apparatuses, including computer programs encoded on computer storage media, which provide for welding techniques for manufacturing robots, such as seam localization, gap measurement, or both. For example, the welding techniques may include, during illumination of one or more objects by a light source, controlling a camera to capture images of the one or more objects along at least a portion of a length of a seam formed by the one or more objects. The techniques further include differentiating, in the images, the seam from the one or more objects. In a first aspect, the techniques also include triangulating the differentiated seam to identify a position of the seam relative to a reference point. In a second aspect, the techniques also include determining, based on the differentiated seam, gap information along a portion of the seam. Other aspects and features are also claimed and described.

### TECHNICAL FIELD

Aspects of the present disclosure relate generally to the field of welding robots, and more particularly, but not by way of limitation, to weldable seam localization, gap measurement, or both.

### INTRODUCTION

Robots configured for manufacturing operations often use vision-based sensors as their eyes. These sensors, such as laser scanners, can be employed to scan a manufacturing workspace that may contain one or more objects e.g., a weldable object. Sensor data produced from the scan can be utilized by a controller, which may be communicably coupled to the robot, to localize—e.g., identify and/or locate—the weldable objects within the manufacturing workspace. Additionally, the sensors can also be configured to generate sensor data that aids in localizing a weldable seam between the weldable objects.

Robotic manufacturing faces various challenges due to one or more factors, such as the complexity of the robots involved in the tasks, variations or tolerances in weldable objects, or a combination of both. For instance, seams between weldable objects often display irregularities, such as variations in gap width along seam length, which may impact the quality of a weld formed along the seam. Often, three-dimensional (3D) point clouds are used to measure the width or gap of the weldable seam. However, using 3D point clouds can be problematic as the weldable seams might appear as empty spaces (e.g., gaps) or voids within the 3D point clouds. Additionally, 3D scanning used in association with generating a 3D point cloud can be susceptible to a surface finish (e.g., a shiny surface, a dull surface, etc.) and a resulting 3D point cloud may indicate a gap in a part where there is in fact an actual surface. Accordingly, a gap or a void in a point cloud may not conclusively indicate that a weldable part includes the gap or void, thereby creating challenges related to processing of or operations determined based on the 3D point cloud. For example, challenges may be created for the segmentation method (e.g., a segmentation method used to identify and/or isolate weldable objects, one or more weldable seams, or other features) in accurately determining gap width and variability along the seam.

### BRIEF SUMMARY OF SOME EXAMPLES

The following summarizes some aspects of the present disclosure to provide a basic understanding of the discussed technology. This summary is not an extensive overview of all contemplated features of the disclosure and is intended neither to identify key or critical elements of all aspects of the disclosure nor to delineate the scope of any or all aspects of the disclosure. Its sole purpose is to present some concepts of one or more aspects of the disclosure in summary form as a prelude to the more detailed description that is presented later.

The present disclosure is related to apparatuses, systems, and methods that provide for seam localization and seam gap measurement. In some implementations, a robotic welding system is configured to control an artificial light source to emit light (e.g., of defined and/or controlled luminosity) at weldable objects. For example, the light may be emitted at multiple weldable objects, such as two or more weldable objects that are positioned to form a weldable seam. When the light is incident on the weldable objects, the robotic welding system is configured to capture images of the weldable objects. The robotic welding system may then utilize the images to localize one or more weldable seams formed between weldable objects. The robotic welding system may then utilize the images to identify one or more features of the weldable objects, such as one or more tack welds that may be used to arrange the weldable objects in a desired configuration. In some implementations, the robotic system is further configured to determine seam gap variability along the length of a weldable seam.

In some implementations, a method of generating instructions for a welding robot by a robot controller of the welding robot includes controlling a light source to emit light at a first object and a second object. The first and second objects are positioned to form a weldable seam. The method further includes, during illumination of the first object, the second object, or a combination thereof by the light source, controlling one or more cameras to capture images of the first and second objects along at least a portion of a length of the weldable seam. The method also includes differentiating, in the images, the weldable seam from the first and second objects, and generating one or more representations (e.g., one or more three-dimensional (3D) representations) associated with the differentiated weldable seam. The method includes determining, based on the one or more representations, gap information along the portion of the weldable seam, and generating, based on the gap information, welding instructions for a welding tool coupled to the welding robot.

In some implementations, a welding robotic system includes a robot device positioned in a workspace, a welding tool coupled to the robotic device, a light source coupled to the robotic device, and a camera coupled to the robotic device and configured to generate image data associated with the workspace. The welding tool is configured to weld together a first object and a second object positioned in the workspace. The welding robotic system further includes a robot controller configured to control the light source to emit light at the first object and the second object. The first and second objects are positioned to form a weldable seam. The robot controller is also configured to, during illumination of the first object, the second object, or a combination thereof by the light source, control the camera to capture images of the first and second objects along at least a portion of a length of the weldable seam. The robot controller is further configured to differentiate, in the images, the weldable seam from the first and second objects, and generate one or more representations (e.g., one or more 3D representations) associated with the differentiated weldable seam. The robot controller may be configured to determine, based on the one or more representations, gap information along the portion of the weldable seam, and generate welding instructions for the welding tool based on the gap information.

In some implementations, a non-transitory computer-readable medium stores instructions that, when executed by a processor, cause the processor to perform operations. The operations include controlling a light source to emit light at a first object and a second object. The first and second objects are positioned to form a weldable seam. The operations further include, during illumination of the first object, the second object, or a combination thereof by the light source, controlling one or more cameras to capture images of the first and second objects along at least a portion of a length of the weldable seam. The operations also include differentiating, in the images, the weldable seam from the first and second objects, and generating one or more representations (e.g., one or more 3D representations) associated with the differentiated weldable seam. The operations include determining, based on the one or more representations, gap information along the portion of the weldable seam, and generating, based on the gap information, welding instructions for a welding tool coupled to the welding robot.

In some implementations, a method of generating instructions for a welding robot by a robot controller of the welding robot includes controlling a light source to emit light at a first object and a second object. The first and second objects are positioned to form a weldable seam. The method further includes, during illumination of the first object, the second object, or a combination thereof by the light source, controlling a camera to capture images of the first and second objects along a length of the weldable seam. The method further includes differentiating, within the images, the weldable seam from the first and second objects. The method includes triangulating the differentiated weldable seam to identify a position of the weldable seam relative to a reference point associated with the welding tool, and generating motion parameters for the welding tool to move the welding tool near the identified position of the weldable seam.

In some implementations, a welding robotic system includes a robot device positioned in a workspace, a welding tool coupled to the robotic device, a light source coupled to the robotic device, and a camera coupled to the robotic device and configured to generate image data associated with the workspace. The welding tool is configured to weld a first object and a second object positioned in the workspace. The welding robotic system further includes a robot controller configured to control the light source to emit light at the first object and the second object. The first and second objects are positioned to form a weldable seam. The robot controller is also configured to, during illumination of the first object, the second object, or a combination thereof by the light source, control the camera to capture images of the first and second objects along a length of the weldable seam. The robot controller is further configured to differentiate, within the images, the weldable seam from the first and second objects. The robot controller is configured to triangulate the differentiated weldable seam to identify a position of the weldable seam relative to a reference point associated with the welding tool, and generate motion parameters for the welding tool to move the welding tool near the identified position of the weldable seam.

In some implementations, a non-transitory computer-readable medium stores instructions that, when executed by a processor, cause the processor to perform operations. The operations include controlling a light source to emit light at a first object and a second object. The first and second objects are positioned to form a weldable seam. The operations further include, during illumination of the first object, the second object, or a combination thereof by the light source, controlling a camera to capture images of the first and second objects along a length of the weldable seam. The operations also include differentiating, within the images, the weldable seam from the first and second objects. The operations include triangulating the differentiated weldable seam to identify a position of the weldable seam relative to a reference point associated with the welding tool, and generating motion parameters for the welding tool to move the welding tool near the identified position of the weldable seam.

In some implementations, a method of generating instructions for a welding robotic system by a robot controller of a welding robot includes receiving a computer-aided design (CAD) model including a representation of a first object and a second object associated with a weldable seam. The method also includes determining, based on the CAD model, one or more light source parameters for controlling a light source, and controlling the light source to emit light at, the first and second objects positioned to form the weldable seam. The method further includes, during illumination of the first object, the second object, or a combination thereof by the light source, controlling one or more cameras to capture images of the first and second objects along a length of the weldable seam. The method includes performing segmentation on the images to identify the weldable seam.

In some implementations, a welding robotic system includes a robot device positioned in a workspace, a welding tool coupled to the robotic device, a light source coupled to the robotic device, and a camera coupled to the robotic device and configured to generate image data associated with the workspace. The welding tool is configured to weld a first object and a second object positioned in the workspace. The welding robotic system further includes a memory storing a CAD model including a representation a first object and a second object associated with a weldable seam, and a robot controller configured to determine, based on the CAD model, one or more light source parameters for controlling a light source, and control the light source to emit light at, the first and second objects positioned to form the weldable seam. The robot controller is further configured to, during illumination of the first object, the second object, or a combination thereof by the light source, control one or more cameras to capture images of the first and second objects along a length of the weldable seam. The robot controller is configured to perform segmentation on the images to identify the weldable seam.

In some implementations, a non-transitory computer-readable medium stores instructions that, when executed by a processor, cause the processor to perform operations. The operations include receiving a CAD model including a representation a first object and a second object associated with a weldable seam. The operations further include determining, based on the CAD model, one or more light source parameters for controlling a light source, and controlling the light source to emit light at, the first and second objects positioned to form the weldable seam. The operations also include, during illumination of the first object, the second object, or a combination thereof by the light source, controlling one or more cameras to capture images of the first and second objects along a length of the weldable seam. The operations include performing segmentation on the images to identify the weldable seam.

Note that the terms “welding” and “joining” are used interchangeably. Welding can be viewed as a type of joining process where materials, often metals, are fused together using heat, pressure, or a combination of both. The terms “welding” and “joining” are meant to describe the union of metals. A “seam” or “unwelded seam” or “weldable seam” in this context refers to the line along which two objects will be joined or welded together.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

A further understanding of the nature and advantages of the present disclosure may be realized by reference to the following drawings. In the appended figures, similar components or features may have the same reference label. For the sake of brevity and clarity, every feature of a given structure is not always labeled in every figure in which that structure appears. Identical reference numbers do not necessarily indicate an identical structure. Rather, the same reference number may be used to indicate a similar feature or a feature with similar functionality, as may non-identical reference numbers.

FIG. 1 is a block diagram illustrating a system configured to enable artificial light-based seam localization and gap measurement techniques in a robotic manufacturing environment according to one or more aspects.

FIG. 2 is a flow diagram illustrating an example process of an artificial light-based seam technique in a robotic manufacturing environment according to one or more aspects.

FIG. 3 is a flow diagram illustrating an example process of an artificial light-based seam localization technique in a robotic manufacturing environment according to one or more aspects.

FIG. 4 is a flow diagram illustrating an example process of an artificial light-based gap measurement technique in a robotic manufacturing environment according to one or more aspects.

FIG. 5 is a flow diagram illustrating an example process of an artificial light-based gap measurement technique in a robotic manufacturing environment according to one or more aspects.

FIG. 6 is a flow diagram illustrating an example process of an artificial light-based seam localization technique in a robotic manufacturing environment according to one or more aspects.

Like reference numbers and designations in the various drawings indicate like elements.

### DETAILED DESCRIPTION

The detailed description set forth below, in connection with the appended drawings, is intended as a description of various configurations and is not intended to limit the scope of the disclosure. Rather, the detailed description includes specific details for the purpose of providing a thorough understanding of the inventive subject matter. It will be apparent to those skilled in the art that these specific details are not required in every case and that, in some instances, well-known structures and components are shown in block diagram form for clarity of presentation.

One solution to the issue related to capturing details from 3D point clouds is to capture details from 2D images instead of 3D point clouds. In certain implementations, this may involve using cameras as sensors to capture 2D images. Segmentation-related algorithms could be applied to these images to localize (e.g., identify and/or locate) a seam, and edge detection algorithms can be applied to determine gap information, such as seam gap information. Nevertheless, seam localization and gap detection using this technique may be computationally complex and may suffer from errors due to changing light conditions, such as ambient light conditions, in the manufacturing workspace. For instance, before capturing the images, the controller may determine an ambient light condition and generate various imaging parameters in response to the determined ambient light condition. These parameters may include a camera pose relative to the weldable objects, and/or other camera-related information such as aperture size, focal length, or exposure time. Calculating these parameters—poses, exposure, and so on—could be computationally demanding and time-consuming. When ambient lighting conditions fluctuate, the controller needs to recompute the optimal imaging parameters from scratch.

The use of 2D images can be less computationally demanding if an artificial light source is introduced to the scene. For instance, this light source could be employed to cast a controlled illumination onto weldable objects, effectively eliminating the impact of ambient light. This aids in seam localization and gap detection. For instance, by using controlled illumination, imaging parameters may need to be determined less frequently, and in some implementations, imaging parameters may need to be computed just once before beginning the image capturing process. Furthermore, with controlled illumination, the imaging parameters may be adjusted to control and provoke a strong contrast between the seam and the weldable objects, such as a much stronger contrast between the seam and the weldable objects as compared to imaging parameters calculated based on ambient light. This strong contrast may help a machine learning logic (e.g., neural network) to localize (e.g., identify and/or locate) the seam and detect the gap along a length of the seam more accurately. It is noted that localization here refers to a process by which position and orientation of an item (e.g., a seam or a feature) within an environment is determined. For example, a controller or control device may be configured to perform the process to determine the position or orientation of an item. In the context of this application, seam localization refers to the process by which a controller (e.g., using images captured by cameras) identifies, locates, and tracks the position and orientation of one or more seams between weldable objects.

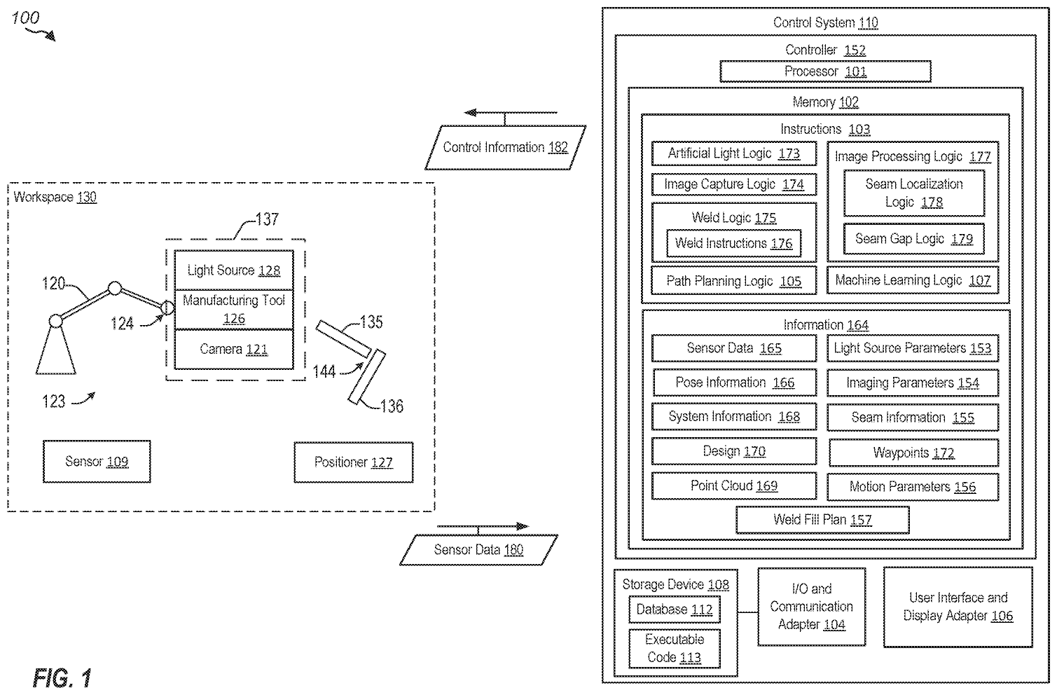

FIG. 1 illustrates a system 100 configured to enable artificial light-based seam localization and gap measurement techniques in a robotic manufacturing environment according to one or more aspects. In some implementations, system 100 may include a processor-based system, an assembly robot system, a welding robot system, or a combination thereof. System 100 of FIG. 1 is configured to enable artificial light-based seam localization techniques, gap measurement techniques, or a combination thereof, for one or more robots (e.g., welding robots) functioning in a semi-autonomous or autonomous manufacturing environment. A manufacturing environment or robot, such as a semi-autonomous or autonomous welding environment or a semi-autonomous or autonomous welding robot, may include one or more artificial light sources, one or more sensors (e.g., cameras) to capture images of the weldable objects in the presence of the light emitted from the one or more artificial light sources, or a combination thereof. Additionally, or alternatively, the semi-autonomous or autonomous manufacturing environment or robot may include the one or more algorithms in the form of software that is configured to differentiate a seam to be welded from one or more objects and other features (e.g., former welds at the seam, such as tack welds) within the captured images, one or more algorithms in the form of software that is configured to triangulate the differentiated seam to localize the seam (localization refers to the identification of the location, position, and/or orientation of the seam), one or more algorithms in the form of software that is configured to determine gap information and/or adjust a position of one or more weldable objects based on the gap information, one or more algorithms in the form of software to program welding instructions and motion of the welding robot, or a combination thereof. The semi-autonomous or autonomous manufacturing environment or robot may also include any other devices, such as a motorized positioner, in order to weld the seams correctly or as desired without collision.

In some implementations, the semi-autonomous or autonomous manufacturing environment or robot may additionally or alternatively include one or more algorithms in the form of software that is configured to triangulate differentiated seams to identify a position of the unwelded seam relative to a reference point, such as a reference point associated with a welding robot, a welding tool, or the like. Additionally, or alternatively, the semi-autonomous or autonomous manufacturing environment or robot may also include one or more algorithms in the form of software that is configured to generate one or more representations, such as one or more three-dimensional (3D) representations (e.g., point cloud representation), of the seam, one or more weldable objects, or a combination thereof. Additionally, or alternatively, the semi-autonomous or autonomous manufacturing environment or robot may also include one or more algorithms in the form of software that is configured to connect multiple representations, such as multiple the 3D representations, of the seam to generate a connected representation of the seam. This could be used to further determine a gap variability, such as the gap variability along a length of the seam. It is noted that a semi-autonomous or autonomous welding robot may have these abilities in part, and where some user given or selected parameters may be required, or user (e.g., operator) involvement may be needed in other ways.

System 100 includes a control system 110, a robot 123, and a manufacturing workspace 130 (also referred to herein as a “workspace 130”). In some implementations, system 100 may include or correspond to a welding robot system. System 100 may be configured to weld one or more objects, such as a first object 135 (e.g., a first weldable object) and a second object 136 (e.g., a second weldable object). In some implementations, first object 135 and second object 136 may be arranged such that they form an unwelded seam 144 (e.g., a weldable seam). Unwelded seam 144 may be a junction between first object 135 and second object 136 along which the objects could be joined (or welded) together. In some implementations, first object 135 and second object 136 may be partially welded (e.g., using tack welds or other kind of welds, collectively referred to herein as “former welds”) into a desired arrangement, and in this desired arrangement, first and second objects 135 and 136 form unwelded seam 144. In other implementations, first object 135 and second object 136 may be positioned and/or in a desired arrangement (for e.g., by robotic arms or positioning systems) without one or more former welds. Each of the first object 135 and second object 136 may be any object, component, subcomponent, or combination thereof that is capable of being joined or fused together with another object through the process of welding or partial welding such as tacking. It is also noted that in some implementations, system 100 may be configured to weld multiple objects together, such as two or more objects—e.g., first object 135, second object 136, and a third object.

In some implementations, the first object 135 and second object 136 may be positioned or held in a desired relative arrangement on or by a positioner 127 using one or more fixture clamps. Example fixture clamps may include strap clamps, screw clamps, swing clamps, edge clamps, C clamps, cam clamps, toggle clamps, and the like. After being affixed in a desired relative arrangement on or by positioner 127, first object 135 and second object 136 may be partially welded—e.g., with one or more tack welds—to formalize this desired relative arrangement. In some implementations, first and second objects 135 and 136 may not be positioned on positioner 127 but rather brought to a desired relative relationship in space using one or more robotic devices such that the objects form an unwelded seam. For instance, one robotic device, equipped with a grasping tool, may be configured to hold the first object 135, while a second robotic device of similar configuration grasps the second object 136. Once grasped by these robotic devices, objects 135 and 136 may be manipulated and brought to achieve a desired spatial configuration, in which they form the unwelded seam.

Robot 123, also referred to herein as “robot device 123”, may be configured to perform a manufacturing operation, such as a welding operation, on one or more objects, such as first object 135 and second object 136. In some implementations, robot 123 may include a robotic device, such as a robotic arm 120 having an attachment point 124 that is configured to attach to one or more components. Robotic arm 120 may have multiple degrees of freedom in that it may be a robotic device configured to operate in six or more axes. Robotic arm 120 may include one or more components, such as a motor, a servo, hydraulics, or a combination thereof, as illustrative, non-limiting examples.

In some implementations, attachment point 124 may be configured to be coupled to one or more components or to one or more end effectors to robotic arm 120. The one or more components may include a light source 128, a camera 121, a sensor, or a combination thereof. The one or more end effectors may include a manufacturing tool 126, such as a weld head Additionally, or alternatively, attachment point 124 may be configured to be coupled to an attachment assembly 137 of one or more components, one or more end effectors, or a combination thereof. In some implementations, attachment point 124 may be configured to be coupled to a housing that includes or is associated with one or more components or one or more end effectors. Additionally, or alternatively, attachment point 124 may attach an artificial light source, such as light source 128 to robotic arm 120. Additionally, or alternatively, attachment point 124 may attach one or more sensors (e.g., image sensors or image capture devices), such as one or more cameras 121 to robotic arm 120.

In some implementations, robotic arm 120 may be coupled (e.g., via attachment point 124) to one or more tools. To illustrate, a tool, such as manufacturing tool 126, may be coupled to an end of robotic arm 120. In some implementations, robotic arm 120 may be coupled to multiple objects, such as manufacturing tool 126 (e.g., a welding head), one or more cameras (e.g., one or more cameras 121), one or more light sources (e.g., light source 128), or a combination thereof. In some implementations, attachment point 124 may attach manufacturing tool 126 (like a weld head) to robotic arm 120, while one or more light sources 128 (or housing thereof) and one or more cameras 121 (or housing thereof) may be coupled to the manufacturing tool 126. In some implementations, attachment point 124 of the robotic arm 120 may attach to the one or more light sources 128 (or the housing that carries the light sources), while manufacturing tool 126 and one or more cameras 121 may be coupled to the light sources (or housing thereof). In some implementations, attachment point 124 of the robotic arm 120 may attach to the one or more cameras 121 (or the housing that carries the cameras 121), while manufacturing tool 126 and one or more light sources 128 may be coupled to the cameras 121 (or housing thereof). In summary, the end effectors such as manufacturing tool 126, one or more cameras 121, light source 128 may be coupled to the robotic arm 120 via attachment point 124 and may be arranged in any relative configuration such that robotic arm 120 along with the attached and coupled end effectors, are to move together within workspace 130. The movement may follow one or more discrete poses, a planned trajectory, and/or weld plan that is received from control system 110.

Although light source 128, manufacturing tool 126, and camera 121 are described as being coupled to the same robot 123, in other implementations at light source 128, manufacturing tool 126, or camera 121 may be coupled to a different robot or structure. In some implementations, the robotic arm 120 may be coupled to manufacturing tool 126, such as via attachment point 124, while the light source 128 and one or more cameras 121 may be coupled to a different robotic arm. In some implementations, all three tools, manufacturing tool 126, light source 128, and one or more cameras 121, may be coupled to different robotic arms via their respective attachment points. In some implementations, robotic arm 120 may be configured to coordinate its movements relative to another device, such as another robotic arm or a positioner 127, as described further below. For the purposes of this disclosure, it is assumed that robotic arm 120, via its attachment point, is coupled to manufacturing tool 126, light source 128, and one or more cameras 121. However, it is noted that the principles defined herein with respect to the robotic arm 120 and the above-noted attachments may be applicable to different configurations of the attachments (e.g., at least one attachment attached to different robotic arm or all attachments attached to different robotic arms) without departing from the spirit or scope of the disclosure.

Robot 123—for example, using robotic arm 120 and one or more light sources 128—is configured to illuminate one or more objects (e.g., objects 136 and 136) in accordance with the received instructions, such as control information 182. Additionally, or alternatively, robot 123—using robotic arm 120 and cameras 121—is further configured to capture multiple images of one or more objects while the objects are illuminated by one or more light sources in accordance with the received instructions, such as control information 182. Additionally, or alternatively, robot 123—using robotic arm 120 and manufacturing tool 126—is yet further configured to perform one or more suitable manufacturing processes (e.g., welding operations) on an unwelded seam between one or more objects in accordance with the received instructions, such as control information 182. In some examples, robotic arm 120 can be a six-axis arm. In some implementations, robotic arm 120 can be any suitable robotic arm, such as YASKAWA® robotic arms, ABB® IRB robots, KUKA® robots, and/or the like. Robotic arm 120, in conjunction with the attached manufacturing tool 126, can be configured to perform arc welding, resistance welding, spot welding, tungsten inert gas (TIG) welding, metal active gas (MAG) welding, metal inert gas (MIG) welding, laser welding, plasma welding, a combination thereof, and/or the like, as illustrative, non-limiting examples. Robotic arm 120 may be responsible for moving, rotating, translating, feeding, and/or positioning the manufacturing tool 126, one or more cameras 121, one or more light sources 128 and/or a combination thereof. In some implementations, robot 123 (and/or another robot) is movable within or with respect to workspace 130. For example, robot 123 may be coupled to or include a movable device, such as a track, rail, wheel, or a combination thereof to enable robot 123 to move within workspace 130. To illustrate, positioner 127, the movable device, or a combination thereof, may move based on or in response to control information 182 received from control system 110 (e.g., controller 152). In some implementations, robot 123 may move, using the movable device, from a first location within workspace 130 to a second location within workspace 130. It is noted that robot 123 may be configured to perform one or more operations as described herein at each location within the workspace 130 that robot 123 may move to or from.

In implementations, robotic arm (e.g., robotic arm 120) may be configured to change (e.g., adjust or manipulate) pose of the one or more end effectors attached and/or coupled thereto in accordance with the received instructions, such as control information 182. For example, a configuration (e.g., joint state) of robotic arm (e.g., robotic arm 120) may be modified to change the pose of manufacturing tool 126, light source 128, one or more cameras 121, or a combination thereof. Although the disclosure focuses on robotic arm 120 being coupled to manufacturing tool 126, light source 128, and one or more cameras 121, the principles defined herein with respect to the robotic arm 120 and the above-noted attachments may be applicable to different configurations of the attachments (e.g., all attachments attached to different robotic arms) without departing from the spirit or scope of the disclosure. For example, in implementations where manufacturing tool 126, light source 128, and one or more cameras 121 are coupled to different robotic arms, each one of the different robotic arms could be configured to change the pose of the end effector attached to it, in accordance with the received instructions, such as control information 182.

Manufacturing tool 126 may be configured to perform one or more manufacturing tasks or operations. The one or more manufacturing tasks or operations may include welding, brazing, soldering, riveting, cutting, drilling, or the like, as illustrative, non-limiting examples. In some implementations, manufacturing tool 126 is a welding tool configured to join or weld two or more objects together. For example, the welding tool may be configured to weld two or more objects together, such as welding first object 135 to the second object 136. To illustrate, the weld tool may be configured to deposit a weld metal along a seam (e.g., 144) formed between first object 135 and second object 136. Additionally, or alternatively, the weld tool may be configured to fuse first object 135 and second object 136 together, such as fusing weld metal along a seam (e.g., 144) formed between first object 135 and second object 136 to weld the objects together. It should be noted that while the disclosure refers to an “unwelded seam”, objects 135 and 136 might be welded together (e.g., by former welds, such as tack welds, or partial welds) in a predefined configuration, with the unwelded seam existing between these former welds (e.g., one or more former welds). Additionally, or alternatively, the weld tool may be configured to form the “former” welds, such as a tack weld or a partial weld, as illustrative, non-limiting examples. In some implementations, manufacturing tool 126 may be configured to perform one or more manufacturing tasks or operations responsive to a manufacturing instruction, such as a weld instruction received via control information 182.

One or more cameras 121 may be enclosed in a housing unit which may be coupled to the robotic arm 120 via an attachment point (e.g., 124) on the robotic arm 120. In some implementations, one or more cameras 121 or the housing unit may be coupled to the manufacturing tool 126, while manufacturing tool 126 is attached to robotic arm 120. In some implementations, one or more cameras 121 may include multiple cameras, for example, two cameras arranged in a stereo configuration (e.g., a stereoscopic configuration). In some implementations, one or more cameras 121 may include a single camera configured to capture images from different viewpoints, thereby creating a stereo effect. In some implementations, the one or more cameras 121 may be configured to capture visual information (e.g., images) about objects 135, 136; one or more seams formed between objects 135, 136; one or more features on the objects 135, 136 or along the seam; or a combination thereof. These features may include former welds (e.g., tack welds) holding objects 135 and 136 in a desired configuration.

In some implementations, one or more cameras 121 may be positioned on robotic arm 120 and may be configured to collect image data in accordance with the received instructions, such as control information 182. The image data may be collected as robotic arm 120 moves (e.g., location, position, and/or orientation) about workspace 130, particularly around or near objects 135 and 136, in accordance with the received instructions, such as control information 182. Because robotic arm 120 is mobile with multiple degrees of freedom and therefore is able to move in multiple dimensions, one or more cameras 121 may capture images from a variety of vantage points or poses. In some implementations, robotic arm having one or more cameras 121 coupled thereto may be operable to move (e.g., rotational or translational motion) such that one or more cameras 121 can capture image data of one or more objects (e.g., 135 or 136), and/or positioner 127 from various poses (e.g., vantage points, angles, and locations). In some implementations, both positioner 127 and one or more cameras 121 may be operable to coordinatively move (e.g., rotational or translational) within the workspace. For instance, first and second objects 135 and 136, respectively may be affixed on positioner 127, and the positioner may rotate, translate (e.g., in x-, y-, and/or z-directions), or otherwise move the objects 135 and 136 within workspace 130, while robotic arm 120 manipulates the pose of one or more cameras 121 to facilitate capturing images of the objects 135 and 136 from different vantage points and poses.

One or more light sources or artificial light sources 128 may also be enclosed in a housing unit. In some implementations, one or more light sources 128 may be enclosed in the same housing unit as the one or more cameras 121. In other implementations, one of more light sources 128 may be enclosed in a housing unit that is different from the housing unit of one or more cameras 121. In implementations where the housing units are different, the housing of the one or more light sources 128 could be coupled to the housing of one or more cameras 121, such that both the housing units are coupled to the same robotic arm, such as robotic arm 120. In implementations where the housing units are different, the housing of the one or more cameras 121 could be coupled to a robotic arm, such as robotic arm 120, while the housing of one or more light sources 128 could be coupled to a robotic arm that is different from the robotic arm 120.

One or more light sources 128 may be configured to produce light in one or more of wavelengths, such as from ultraviolet and visible spectrum to infrared. For example, one or more light sources 128 may include one or more light emitted diodes (LEDs), one or more lasers, or a combination thereof, as illustrative non-limiting examples. In some implementations, one or more light sources 128 includes a single light source configured to produce light in one or more wavelengths. In other implementations, one or more light sources 128 includes multiple light sources. In implementations where one or more light sources 128 includes the multiple light sources, two or more light sources of the multiple lights sources may be configured to emit the same wavelength of light, different wavelengths of light, or a combination thereof. Additionally, or alternatively, the multiple light sources, or a subset thereof, may be configured in a pattern. For example, a first subset may be configured to emit light in a first pattern, a second subset may be configured to emit light in a second pattern, or a combination thereof. In some implementations, a position of one or more light sources 128 may be known. For example, control system 110 may know a position of one or more light sources in relation to a camera.

In some implementations, one or more light sources 128 may be configured to emit lights of different wavelengths. The wavelength of light to be emitted may be selected based on one or more features to be detected or localized, information about an object (e.g., 135 or 136), or a combination thereof. For example, red light (e.g., 620 to 750 nm) could be emitted in association with localizing the seam and determining seam gap variability. As another example, green light could be emitted in association with determining former welds, such as tack welds. As another example, the information about the object may include information from a CAD file that indicates a material of the object, a surface characteristic (e.g., a reflectivity) of the object, or a combination thereof (e.g., shiny stainless steel or dull carbon steel). In some implementations, one or more light sources 128 may emit a single wavelength of light (e.g., red light) to be used in association with localization of multiple different features, such as seams, tack welds, etc. The one or more light sources 128 may be controlled or selected by controller 152 (e.g., artificial light logic 173), as described further herein.

Workspace 130 may also be referred to as a manufacturing workspace. Workspace 130 may be or define an area or enclosure within which robot arm(s), such as robotic arm 120, operates on one or more objects (such as objects 135 and 136) based at least in part on or in conjunction with information (e.g., images) from one or more cameras 121. In some implementations, workspace 130 can be any suitable welding area designed with appropriate safety measures for welding. For example, workspace 130 can be a welding area located in a workshop, job site, manufacturing plant, fabrication shop, and/or the like. In some implementations, at least a portion of system 100 is positioned within workspace 130. For example, workspace 130 may be an area or space within which one or more robot devices (e.g., a robot arm(s) such as robotic arm 120) are configured to operate on one or more objects. The one or more objects (e.g., objects 135 and 136) may be positioned on, coupled to, stored at, or otherwise supported by one or more platforms, containers, bins, racks, holders, or positioners. An example positioner 127 is shown in FIG. 1. One or more objects (e.g., 135 or 136) may be held/positioned on positioner 127 using fixtures and/or clamps, as described above. In some examples, workspace 130 may include one or more cameras 121, positioner 127, robotic arm 120, light source 128, sensor 109, and manufacturing tool 126 that is configured to perform welding on one or more objects.

Sensor 109 may be configured to capture data (e.g., images, audio data) related to entities present in the workspace 130. Sensor 109 may include an image sensor, such as a camera, a scanner, a laser scanner, a camera with in-built laser sensor, or a combination thereof. In some implementations, sensor 109 is an image sensor that is configured to capture visual information (e.g., images) about workspace 130 and the entities (e.g., robot 123, positioner 127, objects 135 and 136, and the like) present in the workspace 130. In some implementations, sensor 109 may include a Light Detection and Ranging (LiDAR) sensor, an audio sensor, electromagnetic sensor, or a combination thereof. The audio sensor, such as a Sound Navigation and Ranging (SONAR) device, may be configured to emit and/or capture sound. The electromagnetic sensor, such as a Radio Detection and Ranging (RADAR) device, may be configured to emit and/or capture electromagnetic (EM) waves. Through visual, audio, electromagnetic, and/or other sensing technologies, sensor 109 may collect information about physical structures (e.g., (e.g., robot 123, positioner 127, objects 135 and 136, and the like) in workspace 130. Additionally, or alternatively, sensor 109 is configured to collect static information (e.g., stationary structures in workspace 130), dynamic information (e.g., moving structures in workspace 130), or a combination thereof.

Sensor 109 may be configured to capture data (e.g., image data) of workspace 130 from various positions and angles. In some implementations, sensor 109 may be mounted onto a robotic device (e.g., dynamic robot movable on a track or a planned path) configured to move around the workspace 130. For example, sensor 109 may be positioned on robotic device similar to robotic arm 120 and may be configured to collect image data as this robotic device moves (e.g., rotational or translational motion) about workspace 130 (e.g., on fixed tracks or on wheels). This robotic device may be mobile with multiple degrees of freedom and therefore in multiple dimensions, sensor 109 may capture images from a variety of vantage points and poses. (e.g., rotational or translational motion) such that sensor 109 can capture image data of entities within the workspace 130 from various angles. In some implementations, sensors 109 may be stationary while entities or physical structures to be imaged are moved about or within workspace 130. For instance, one or more objects (e.g., 135 or 136) to be imaged may be positioned on positioner 127, such as a positioner, and the positioner and/or the part may rotate, translate (e.g., in x-, y-, and/or z-directions), or otherwise move within workspace 130 while a stationary sensor 109 captures multiple images of various facets of the objects 135 and 136.

In some implementations, sensor 109 may collect or generate information, such as images or image data, about one or more physical structures in workspace 130. The data captured by sensor 109 could be used by a controller (e.g., 152) to determine positions and locations of one or more physical structures in workspace 130. For example, sensor 109 may capture images of the objects within workspace 130 from a variety of vantage points and poses. (e.g., rotational or translational motion) and controller 152 may use these images to create a map or model of workspace 130. This map could inform controller 152 relative location and positions of various objects within the workspace. In some instances, sensor 109 may be configured to image or monitor a weld laid by manufacturing tool 126, before, during, or after the welding process. Stated another way, the information may include or correspond to a geometric configuration of a seam, the weld laid by manufacturing tool 126, or a combination thereof. The geometric configuration may include 3D point cloud information, mesh, image of a slice of the weld, point cloud of the slice of the weld, or a combination thereof, as illustrative, non-limiting examples.

Positioner 127 may be configured to hold, position, and/or manipulate one or more objects (135, 136). Positioner 127 may include a clamp, a platform, or other types of fixtures, as illustrated, non-limiting examples. In some implementations, positioner 127 has a headstock and tailstock configuration in which an object (e.g., 135) can be securely held at both ends by the headstock and tailstock, facilitating rotation through manipulation by the headstock and tailstock. In some such implementations, another object (e.g., 136) can be positioned with respect to the object held by positioner 127. The two objections (e.g., 135 and 136) may then be tack welded to maintain the objects in a desired configuration. In such scenarios, after the objects are tack welded together, the headstock and tailstock configuration allows for the rotational manipulation of both objects. In some examples, positioner 127 is adjustable. For example, positioner 127 may dynamically adjust its position, orientation, or other physical configuration prior to or during a welding process, e.g., based on instructions received from control system 110 via control information 182. The positioner 127 may receive instructions (e.g., 182) from control system 110 to dynamically adjust its position and orientation. The instructions may be related to adjusting the welding position of the seam relative to manufacturing tool 126. For example, during the welding process, the control system 110 may coordinate and adjust position and orientation of positioner 127 to ensure that objects 135, 136 are held in specific weld positions, such as 1F or 2F, making sure that the seam aligns substantially perpendicularly to the force of gravity. To illustrate, controller 152 may send instructions (e.g., control information 182) to positioner having the headstock and tailstock configuration to cause objects 135, 136 to be held in a specific weld position, such as 1F or 2F.

In some implementations, positioner 127 is movable within or with respect to workspace 130. For example, positioner 127 may be coupled to or include a movable device, such as a track, rail, wheel, or a combination thereof to enable positioner 127 to move within workspace 130. In some implementations, positioner 127 may move, using the movable device, from a first location within workspace 130 to a second location within workspace 130. To illustrate, positioner 127, the movable device, or a combination thereof, may move based on or in response to control information 182 received from control system 110 (e.g., controller 152). It is noted that positioner 127 may be configured to perform one or more operations as described herein at each location within the workspace 130 that positioner 127 may move to or from.

Control system 110 is configured to operate and control a robot 123, positioner 127, or a combination thereof, to perform manufacturing functions in workspace 130. For instance, control system 110 can operate and/or control robot 123 to perform welding operations on one or more objects, operate and/or control positioner 127 to position one or more objects in a desired position to enable a region of interest of the one or more objects to be scanned or welded, or a combination thereof. Additionally, or alternatively, if objects (e.g., 135 and 136) are held by different robot arm, control system 110 may be configured to move the robot arms in a coordinated fashion so as to present the objects in a desired position and orientation to scan or weld the object—while maintaining a relative position and orientation of the objects during the scan operation and/or weld operation. Although described herein with reference to a welding environment, the manufacturing environment may include one or more of any of a variety of environments, such as assembling, painting, packaging, and/or the like. In some implementations, workspace 130 may include one or more objects (e.g., 135, 136) to be welded. The one or more objects may be formed of one or more different parts. For example, the one or more objects may include a first object (e.g., 135) and a second object (e.g., 136), and the first and second objects form at least an unwelded seam (e.g., 144) at their interface. In some implementations, the first and second objects may be held together in a preferred configuration using tack welds. In other implementations, the first and second objects may not be welded (e.g., physically coupled) and robot 123 performs tack welding on the unwelded seam of the first and second objects so as to lightly bond the parts together in a desired configuration. Additionally, or alternatively, following the formation of the tack welds, robot 123 may weld additional portions of the unwelded seam to tightly join or bond the objects together.

In some implementations, robot 123 may be presented with objects and may implement an imaging or scanning technique in an artificial light-rich environment to identify the location, position, or orientation, (or a combination thereof) of unwelded seam 144. Based on imaging and/or scanning the objects, control system 110 may identify one or more locations to perform a welding operation to tack weld the objects together in a desired configuration. Additionally, or alternatively, robot 123 may be presented with objects already tack welded, and in such implementations, robot 123 may implement an imaging or scanning technique in an artificial light-rich environment to identify the location, position, or orientation, (or a combination thereof) of unwelded seam 144. The foregoing scanning technique may also be employed to determine seam gap variability along the length of the seam (e.g., from or to a tack weld, or between two tack welds). Following the identification of the location, position, or orientation, (or a combination thereof) of unwelded seam 144, robot 123 may perform a welding operation to tack weld the objects together or lay weld material along the seam 144 to form a joint. Additionally, or alternatively, robot 123 may also be configured to dynamically adapt welding operation based on the determined seam gap variability.

In some implementations, control system 110 may be implemented externally with respect to robot 123. For example, control system 110 may include a server system, a computer system, a notebook computer system, a tablet system, or a smartphone system, to provide control of robot 123 (e.g., a semi-autonomous or autonomous welding robot), positioner 127, or a combination thereof. Although control system 110 is shown as being separate from robot 123, a portion or an entirety of control system 110 may be implemented internally to robot 123, positioner 127, or a combination thereof. For example, the portion of control system 110 internal to robot 123 may be as included as a robot control unit, an electronic control unit, or an on-board computer, and may be configured to provide control of robot 123, such as a semi-autonomous or autonomous welding robot.

Control system 110 implemented internally or externally with respect to robot 123 may collectively be referred to herein as “robot controller 110”. Control system 110 may include one or more components. For example, control system 110 may include a controller 152, one or more input/output (I/O) and communication adapters 104 (hereinafter referred to collectively as “I/O and communication adapter 104”), one or more user interface and/or display adapters 106 (hereinafter referred to collectively as “user interface and display adapter 106”), and a storage device 108. In some implementations, control system 110 may also include one or more sensors 109 (hereinafter referred to as “sensor 109”). The controller 152 may include a processor 101 and a memory 102. Although processor 101 and memory 102 are both described as being included in controller 152, in other implementations, processor 101, memory 102, or both may be external to controller 152, such that each of processor 101 or memory 102 may be one or more separate components.

Controller 152 may be any suitable machine that is specifically and specially configured (e.g., programmed) to perform one or more operations attributed herein to controller 152, or, more generally, to system 100. In some implementations, controller 152 is not a general-purpose computer and is specially programmed or hardware-configured to perform the one or more operations attributed herein to controller 152, or, more generally, to control system 110 and system 100. Additionally, or alternatively, the controller 152 is or includes an application-specific integrated circuit (ASIC), a central processing unit (CPU), a field programmable gate array (FPGA), or a combination thereof. In some implementations, controller 152 includes a memory, such as memory 102, storing executable code, which, when executed by controller 152, causes controller 152 to perform one or more of the actions attributed herein to controller 152, or, more generally, to system 100. Controller 152 is not limited to the specific examples described herein.

In some implementations, controller 152 is configured to control sensor(s) 109, robot 123, positioner 127 within workspace 130. For example, controller 152 may control robot 123 to perform scanning operations or welding operations and to move within workspace 130 according to path planning and/or weld planning techniques. As another example, controller 152 may also manipulate positioner 127 to rotate, translate, or otherwise move one or more parts within workspace 130. Additionally, or alternatively, controller 152 may control sensor(s) 109 to move within workspace 130 and/or to capture images (e.g., 2D or 3D), audio data, and/or EM data. Additionally, or alternatively, controller 152 may manipulate robot 123 (including robotic arm 120, light source 128, or cameras 121, or combination thereof), sensor 109, and positioner 127 in coordination with each other.

In some implementations, controller 152 may also be configured to control other aspects of system 100. For example, controller 152 may further interact with user interface (UI) and display adapter 106. To illustrate, controller 152 may provide a graphical interface on UI and display adapter 106 by which a user may interact with system 100 and provide inputs to system 100 and by which controller 152 may interact with the user, such as by providing and/or receiving various types of information to and/or from a user (e.g., identified seams that are candidates for welding, possible paths during path planning, possible locations for tack welds along a length of a seam, welding parameter options or selections, etc.). UI and display adapter 106 may be any type of interface, including a touchscreen interface, a voice-activated interface, a keypad interface, a combination thereof, etc.

In some implementations, control system 110 may include a bus (not shown). The bus may be configured to couple, electrically or communicatively, one or more components of control system 110. For example, the bus may couple controller 152, processor 101, memory 102, I/O and communication adapter 104, and user interface and display adapter 106. Additionally, or alternatively, the bus may couple one or more components or portions of controller 152, processor 101, memory 102, I/O and communication adapter 104, and user interface and display adapter 106.

Processor 101 may include a central processing unit (CPU), which may also be referred to herein as a processing unit. Processor 101 may include a general-purpose CPU, such as a processor from the CORE family of processors available from Intel Corporation, a processor from the ATHLON family of processors available from Advanced Micro Devices, Inc., a processor from the POWERPC family of processors available from the AIM Alliance, etc. However, the present disclosure is not restricted by the architecture of processor 101 as long as processor 101 supports one or more operations as described herein. For example, processor 101 may include one or more special purpose processors, such as an application specific integrated circuit (ASIC), a graphics processing unit (GPU), a field programmable gate array (FPGA), etc.

Memory 102 may include a storage device, such as random-access memory (RAM) (e.g., SRAM, DRAM, SDRAM, etc.), ROM (e.g., PROM, EPROM, EEPROM, etc.), one or more HDDs, flash memory devices, SSDs, other devices configured to store data in a persistent or non-persistent state, or a combination of different memory devices. Memory 102 is configured to store user and system data and programs, such as may include some or all of the aforementioned program code for performing functions of seam localization and gap measurement and data associated therewith.

Memory 102 includes or is configured to store instructions 103 and information 164. In one or more aspects, memory 102 may store the instructions 103, such as executable code, that, when executed by the processor 101, cause processor 101 to perform operations according to one or more aspects of the present disclosure, as described herein. In some implementations, instructions 103 (e.g., the executable code) is a single, self-contained, program. In other implementations, the instructions (e.g., the executable code) is a program having one or more function calls to other executable code which may be stored in storage or elsewhere. The one or more functions attributed to execution of the executable code may be implemented by hardware. For example, multiple processors may be used to perform one or more discrete tasks of the executable code.

Instructions 103 may include artificial light logic 173, image capture logic 175, image processing logic 177, path planning logic 105, weld logic 175, and machine learning logic 107. Information 164 may include or indicate sensor data 165, pose information 166, system information 168, design 170 (e.g., a CAD model or CAD information), point cloud 169, light source parameters 153, imaging parameters 154, seam information 155, waypoints 172, motion parameters 156, and weld fill plan 157.

Artificial light logic 173 is configured to determine or control operation of light source 128. For example, artificial light logic 173 may be configured to determine or generate light source parameters 153. In some implementations, artificial light logic 173 may determine light source parameters 153 based on imaging parameters 154, seam information 155 (e.g., a seam location), a CAD model, such as design 170, or a combination thereof. The CAD model may include a representation of the first object 135 and second object 136 associated with or that define seam 144, one or more annotations associated with first object 135, second object 136, or seam 144, or a combination thereof. In some implementations, the CAD model may include one or more annotations that indicate one or more weld parameters, one or more object parameters (e.g., material type), other information, or a combination thereof. In some implementations, an annotation associated with the seam may have been annotated by an operator/user.

In some implementations, artificial light logic 173 may determine light source parameters 153 based on imaging parameters 154, such as light source parameters to be applied to one or more light sources 128. For example, light source parameters 153 may be selected to enable or promote camera 121 to capture an image having one or more qualities, such as contrast (e.g., high contrast). The contrast may include or be associated with a contradiction in color that makes an object or feature distinguishable. For example, in visual perception of the real world, contrast may be determined by the difference in the color and brightness of the object and other objects within the same field of view. In some implementations, artificial light logic 173 may configure a first light source to have a first characteristic (e.g., a first set of light source parameters) and a second light source to have a second characteristic (e.g., a second set of light source parameters) that is different from the first characteristic. For example, artificial light logic 173 may generate light source parameters 153 to cause light source 128 to produce light in a variety of wavelengths including ultraviolet, visible spectrum, infrared, or a combination thereof, as illustrative, non-limiting examples. To illustrate, the first light source may be configured to emit red light to localize seam 144 and determine seam gap variability. Alternatively, the second light source may be configured to emit green light to be used to identify tack welds. In some implementations, such as in the case of different wavelengths where one light source emits red light and another light source emits green light, controller 152 may first make the green light emit (while taking images) to identify tacks, and then use the red light (while taking images) to localize the seam and determine gap variability between the tacks. Additionally, or alternatively, controller 152 may identify one or more former welds, localize the seam, determine gap variability, or a combination thereof using an image captured during light having a first wavelength being emitted, a second image captured during light having a second wavelength being emitted, or both the first and second image. Accordingly, light source 128 may be configured to switch between different wavelengths, allowing adaptability to more accurate detection of various features.

In other implementations, such as when one or more light sources 128 include a single light source, artificial light logic 173 may configure the light source parameters 153 for the single light source to emit light having a single wavelength or light having different wavelength (e.g., a red light followed by a green light). The controller 152 may use the single light source to emit light (e.g., having the single wavelength or having different wavelengths at different times) to perform both seam localization and gap measurement.

In some implementations, artificial light logic 173 (or controller 152) may determine light source parameters 153, or which light source should be activated, based on information about an object (135, 136). For example, the information may include or correspond to an annotation of a CAD model. The information may include or indicate a material of the object, a surface finish of the object, a geometry of the object, or a combination thereof, as illustrative, non-limiting examples. Artificial light logic 173 (or controller 152) may select a light source to have first light source parameters (153) based on the object having a shiny stainless steel material or second light source parameters (153) based on the object having a dull carbon steel. Additionally, or alternatively, artificial light logic 173 (or controller 152) may configure or select one or more light source to have a pattern to produce structured projections of light onto a scene (of one or more objects). The pattern may be configured to enable image processing to better disambiguate real gaps on the part from false positives gaps.

Additionally, or alternatively, artificial light logic 173 may determine light source parameters 153 based on seam information 155, the CAD model (e.g., design 170), or a combination thereof. For example, artificial light logic 173 may determine light source parameters 153 based on a surface location of an object (e.g., 135, 136), an expected surface location of seam 144 specified by the CAD model (e.g., design 170), or a combination thereof, such that the light emitted by light source 128 is substantially perpendicular to the surface, is aligned with a seam normal line (e.g., a normal vector) associated with seam 144, or a combination thereof. As another example, artificial light logic 173 may determine an angle of incidence of the emitted light relative to the first object, the second object, or a combination thereof. The angle of incidence is determined using a CAD model including a representation of the at least one unwelded seam. For example, the CAD model may include or correspond to design 170. To illustrate, controller 152 may determine the angle of incidence (or in other words the pose) of the light source based on the CAD model. The angle of incidence may be determined based on one or more seam normal lines associated with the unwelded seam, based on a normal line associated with a surface of the first object or a surface of the second object, or a combination thereof. In some implementations, the angle of incidence is determined to increase a contrast between different surfaces included in the images, such as a surface of the first object and a surface of the second object, as an illustrative, non-limiting example. In some implementations, controller 152 may select a particular light source to be used. The particular light source may have a location, such as known location with respect to a camera or may be positioned on a different robot than the camera. The controller 152 may also be configured to adjust a pose of the selected light source. Additionally, or alternatively, controller 152 may cause one or more light sources 128 to illuminate the first and second objects with light from one or more light sources 128 to bring about first light on a surface of the first object, second light on a surface of the second object, or a combination thereof. The illuminated surfaces of the first object and/or the second object, or the unwelded seam, may be differentiated in the images based on the contrast in the first and second lights. Additionally, or alternatively, controller 152 may cause one or more light sources 128 to illuminate the first and second objects with first light having a first pattern, second light having a second pattern, or wavelengths, or a combination thereof.

In some implementations, artificial light logic 173 is configured to control operation of light source 128 based on light source parameters 153. To illustrate, as described above, artificial light logic 173 may be configured to adjust a pose of light source 128, adjust one or more characteristics of light source or light emitted from light source 128, activate or deactivate light source 128, or a combination thereof, as illustrative, non-limiting examples. In some implementations, artificial light logic 173 may be configured to control operation of light source 128 in conjunction with image capture logic 174, imaging parameters 154, or a combination thereof. Additionally, or alternatively, in some implementations, artificial light logic 173 may be part of image capture logic 174.

Image capture logic 175 is configured to determine or control the operation of camera 121. For example, image capture logic 175 may be configured to determine or generate imaging parameters 154 (e.g., a camera pose, a camera position, an aperture size, a focal length, an exposure time, or a combination thereof). In some implementations, image capture logic 175 may determine imaging parameters 154 based on light source parameters 153, seam information 155 (e.g., a seam location), the CAD model, or a combination thereof. Image capture logic 175 may be configured to control camera 121 to capture multiple images of one or more objects, such as while the objects are illuminated by one or more light sources (e.g., 127) or while the objects are not illuminated by one or more lights sources (e.g., 127). In some implementations, image capture logic 175 may determine a first parameter, such as a camera pose or camera position, of the imaging parameters 154. Controller 152 instructs to capture image and camera 121 determines one or more imaging parameters, such as an aperture size, a focal length, an exposure time, or a combination thereof. In some implementations, camera 121 may determine the one or more imaging parameters while the objects are illuminated by one or more light sources (e.g., 127) or while the objects are not illuminated by one or more lights sources (e.g., 127).

In some implementations, image capture logic 175 may be configured to determine imaging parameters 154 based on or in relation to seam 144. For example, image capture logic 175 may identify a position of seam 144 and determine a normal vector associated with the seam 144. The normal vector of a seam is a vector that is perpendicular to a seam, such as a surface of the seam or a direction of the seam. In some implementations, the normal vector associated with seam 144 may be determined based on a CAD model of the seam, such as based on a geometry of seam 144 or objects 135, 136, an annotation associated with seam 144, or a combination thereof. In some implementations, image capture logic 175 (or controller 152) may determine an imaging parameter (e.g., 154) based on a CAD model, such as based on a seam that is annotated and represented in this model. That is, image capture logic 175 (or controller 152) may determine the imaging parameter based on an estimation of where seam 144 is, according to the CAD model. An illustrative example of an estimation of a seam based on a CAD model is described with reference to U.S. Pat. No. 11,759,958, which is incorporated herein by reference.

Image capture logic 175 may determine a camera pose or a camera position based on or relative to the normal vector associated with seam 144. Determining the camera pose or the camera position based on the normal vector associated with seam 144 may enable camera 121 to capture a high resolution image of seam 144 or a gap region associated with seam 144. As an example, when camera 121 is a stereo camera, image capture logic 175 may determine a camera pose or a camera position such that the two lenses of the stereo camera are positioned on either side of the normal vector. As another example, when camera 121 includes a single camera (or two separate cameras), the camera may determine a first camera pose that is substantially aligned with the normal vector, a second camera pose to a first side of the normal vector, a third camera pose to a second side of the normal vector, or a combination thereof. It is noted that determining a camera pose for a stereo camera, or multiple cameras, may include determining the camera pose such that a first camera is positioned on one side of the normal vector and a second camera is positioned to another side of the normal vector.

Determining a camera pose for a stereo camera or multiple camera poses for a single camera may enable triangulation to be performed using one or more captured images. For example, the triangulation may be performed to determine a position or a size of a gap region. Triangulation performed using images captured from a camera having a camera pose determined by image capture logic 175 may have high precision and may enable determining a position or gap size of seam 144 with high accuracy.

Image processing logic 177 is configured to perform one or more image processing operations. Image processing logic 117 may include seam localization logic 178, seam gap logic 179, or a combination thereof. Image processing logic 177 may be configured to receive image data, such as one or more images. In some implementations, the image data was generated while one or more light sources 128 were active. The image data may include or correspond to image data produced by camera 121, sensor data 165 or 180, or a combination thereof, and may include 2D image data. In some implementations, image processing logic 177 is operable to process image data from camera 121 to assemble two-dimensional data for further processing.

In some implementations, image processing logic 177 is configured to perform the image processing operations to identify or recognize first object 135 or a surface thereof, second object 136 or a surface thereof, seam 144 or a gap thereof, a weld (e.g., a tack weld), or a combination thereof. In some implementations, image processing logic 177 may be configured to use a neural network to perform a pixel-wise classification and/or point-wise classification to identify and classify structures within workspace 130. To illustrate, controller 152, upon execution of instructions 103 or executable code 113, may use a neural network to perform the pixel-wise classification and/or the point-wise classification to identify and classify structures within workspace 130. For example, controller 152 may perform the pixel-wise classification and/or the point-wise classification to identify one or more imaged structures within workspace 130 as an object (e.g., 135 or 136), as a seam on the part or at an interface between multiple parts, as positioner 127, as robot 123, etc.

In some implementations, image processing logic 177 may produce (e.g., generate) seam information, such as a series of waypoints (e.g., 172) associated with seam 144, normal information associated with the seam, or a combination thereof. For example, based on identification of a seam (e.g., 144), image processing logic 177 may generate multiple waypoints (e.g., 172) along the seam based on a 3D representation of the seam. For example, seam localization logic 178 may discretize seam 144 into a series of multiple waypoints. The multiple waypoints may include a set of points. Each waypoint can be configured to constrain an orientation of the weld head of a welding robot (e.g., welding robot 123) in three or more degrees of freedom. For example, each waypoint may restrict the motion and/or orientation of the weld head along three translational axes and two rotational axes (e.g., fixing the position and weld angle).

In some implementations, image processing logic 177 may use a mesh of a part as an input and output a set of waypoints and surface normal information that represents a feature in an appropriate way for planning, such as path planning, welding planning, etc.. Additionally, or alternatively, image processing logic 177 may use annotated features (e.g., annotation information) from design 170 to produce the series of waypoints 172, the normal information, or a combination thereof. In some implementations, the seam information may include or indicate an S1 direction (e.g., a vector at a waypoint that indicates a first surface tangent), an S2 direction (e.g., a vector at the waypoint that indicates a second surface tangent), a travel direction (e.g., of a weld head and that is normal to a plane associated with a weld profile that passes through the waypoint, such as a slice mesh at the waypoint), as illustrative, non-limiting examples.

Additionally, or alternatively, image processing logic 177 may be configured to perform segmentation on the image data (e.g., the images) to identify seam 144, a gap of seam 144, or a combination thereof. For example, image processing logic 177 may be configured to perform the segmentation to differentiate, within the images, seam 144 from first and second objects 135, 136. As another example, image processing logic 177 may be configured to perform the segmentation to differentiate seam 144 to be welded from one or more objects and other features (e.g., former welds at the seam, such as tack welds) within the captured images.

In some implementations, image processing logic 177 is configured to perform triangulation using two or more images captured within workspace 130. The triangulation may be performed to generate one or more 3D representations, such as a 3D representation of an object or a seam associated with the object. Triangulation may be performed using the two or more images may be captured using camera 121 at a known location, at a known pose, or having a known frame of reference. For example, the two or more images may be from multiple angles in a variety of positions within workspace 130. Additionally, or alternatively, in some implementations, image processing logic 177 may use a single image for triangulation if a location of a light source (e.g., 128) is known in relation to camera 121. To illustrate, if the location of light source 128, such as a laser or LED, is known in relation to camera 121, image processing logic 177 may process a geometry of an object that is being illuminated by analyzing the laser line or shadows and thereby perform triangulation using a single image. In some implementations, image processing logic 177 may use multiple images for triangulation and/or generation of one or more representations. To illustrate, multiple images may be used because an object or a seam may be larger than can be captured (e.g., by camera 121 at a particular pose or position) with a single image, acquiring one or more additional images, such as multiple images from several capturing poses, may provide more information to robustly localize the seam or object in 3D space, capturing images in multiple orientations may provide spatial information about an object in three dimensions, or a combination thereof.

In some implementations, seam localization logic 178 is configured to perform seam identification/detection or seam localization. For example, seam localization logic 178 may include or perform one or more algorithms configured to triangulate a differentiated seam to localize the seam (localization refers to the identification of the location, position, and/or orientation of the seam). In some implementations, seam localization logic 178 may triangulate the differentiated seam to identify a position of the seam relative to a reference point (e.g., a frame of reference or a point of reference), such as a frame of reference of robot 123, as an illustrative, non-limiting example. For example, the point of reference may be associated with robot 123, associated with manufacturing tool 126 coupled to robot 123, associated with a frame of reference of camera 121, a frame of reference associated with positioner 127, a frame of reference associated with a light source (e.g., 128), a frame of reference with respect to a known location, or a combination thereof.

In some implementations, to triangulate the seam, seam localization logic 178 may determine a position (of the seam) relative to a frame of reference of camera. Seam localization logic 178 may transform the position to a frame of reference of positioner 127. The frame of reference associated with camera 121 may be different from the frame of reference associated with positioner device 127. Seam localization logic 178 may generate a 3D representation based on the transformed position. The 3D representation may include or correspond to point cloud 169.

Seam localization logic 178 may be configured to triangulate the differentiated seam to generate one or more 3D representations (e.g., 169) of the seam. For example, seam localization logic 178 may include or execute one or more algorithms that triangulate differentiated seams to generate one or more three-dimensional (3D) representations (e.g., point cloud representation) of the seam. The 3D representations may include or correspond to point cloud 169. In some implementations, triangulation includes calculating a position of a point (or multiple points along the seam) by measuring angles to the point from a known reference, such as a camera's frame of reference, a frame of reference of a light source, or a positioner's frame of reference. In some implementations, seam localization logic 178 may include or execute one or more algorithms that connect multiple of the 3D representations of the seam to generate a connected representation of the seam. At least one 3D representation, or the connected representation, may be used by seam gap logic 179 to determine the gap information (e.g., a gap size or gap variability) along a length of the seam.

In some implementations, seam localization logic 178 may be configured to determine a location to form a former weld (e.g., a tack weld or a partial weld) to coupled objects 135, 136 in a desired relationship. In some implementations, seam localization logic 178 may identify or determine a location to form a former weld if a gap measurement or gap variability, as determined by seam gap logic 179, of seam 144 is less than or equal to a threshold.

In some implementations, seam gap logic 179 may determine gap information. For example, seam gap logic 179 may determine the gap information based on one or more 3D representations. The gap information may include or indicate one or more dimensions of a seam (e.g., 144). The one or more dimensions may include a size (e.g., a depth, a width, or both) of a gap of the seam, a depth of the seam, a width of the seam, a length of the seam, or a combination thereof. To determine the gap information, seam gap logic 179 may determine a seam position and orientation, such as seam position information, seam orientation information, or a combination thereof. After determining the seam position or orientation, seam gap logic 179 may detect one or more edges that form or define the seam. For example, controller 152 may use an edge detection technique, such as Canny detection, Kovalevsky detection, another first-order approach, or a second-order approach, to detect the one or more edges. In some implementations, seam gap logic 179 may use a supervised or self-supervised neural network to detect the one or more edges. The detected edges may be used to determine a variability in the gap (e.g., one or more dimensions of the gap) along the length of the seam. The gap variability may be determined based on how the one or more dimensions vary along a length of the seam. In some implementations, seam gap logic 179 may identify and/or measure a gap along the seam at each waypoint. The gap variability along a length of seam 144 may be determined based on the measured gap at multiple waypoints. In some instances, the variability in gaps may be identified within or based on the 3D point cloud generated using the images captured by camera 121.

In some implementations, image processing logic 177 may be configured to detect seam 144, a gap associated with seam 144, a former weld associated with seam 144, or a combination thereof. In some such implementations, image processing may detect seam 144, the gap, the former weld, or a combination thereof using 2D image data and without performing triangulation. For example, image processing logic 177 may detect the presence of seam 144 and determine the seam information, the presence of the gap and determine gap information, or a combination thereof. Additionally, or alternatively, image processing logic 177 may evaluate the gap, one or more measurements associated with the gap, or a gap variability. For example, image processing logic 177 may evaluate the gap, the one or more measurements associated with the gap, or the gap variability to determine if two objects are positioned in a particular relationship—e.g., if a separation between the two objects is greater than or equal to a threshold distance, or if the separation between the two objects is less than or equal to the threshold distance. The threshold distance may be indicated in a CAD model or an annotation included in the CAD model. If the separation is less than or equal to the threshold distance, controller 152 may then perform one or more operations associated with planning or forming a weld, such as a former weld (e.g., a tack weld) or laying a weld within seam 144. Alternatively, if the separation is greater than or equal to the threshold distance, controller 152 may perform one or more operations to adjust a position of or both of the objects. After a position of one or both of the objects is adjusted, controller 152 may capture a new image and process the new image to again evaluate a gap between the two objects is greater than or equal to the threshold distance. Accordingly, controller 152 may use seam localization and gap analysis to inspect a fit between two object, evaluate the quality of fit-up, or identify gaps or inconsistencies in fit-up.

Path planning logic 105 is configured to generate a path (e.g., a movement path) associated with movement of robot 123. To generate the path, path planning logic 105 may generate motion parameters 156 associated with movement of manufacturing tool 126. For example, path planning logic 105 may generate motion parameters 156 for moving manufacturing tool 126 near seam 144. To illustrate, path planning logic 105 may generate motion parameters 156 based on a position (e.g., seam information 155) of seam 144, point cloud 169, or a combination thereof, to move manufacturing tool near seam 114 for a scanning operation, a welding operation, or a combination thereof. In some implementations, motion parameters 156 generated by path planning logic 105 may include instructions to move robot 123 near seam 144 to thereby align manufacturing tool 126 for performance of a welding operation.

Weld logic 175 is configured to plan or control one or more manufacturing processes (e.g., welding operations) associated with seam 144. For example, weld logic 175 may generate weld instructions 176 to cause robot 123 (e.g., manufacturing tool 126) to perform a weld operation. To illustrate, weld instructions 176 may be associated with welding that is performed in a single pass, i.e., a single pass of welding is performed along seam 144, or welding that is performed in multiple passes. In some implementations, weld logic 175 may be configured to enable multipass welding, which is a welding technique in which robot 123 makes multiple passes over seam 144. For example, weld logic 175 may be configured to determine an optimal number of weld passes and the subsequent weld parameters to fill a weld joint. The weld joint can have volumetric variation and the weld parameters will adapt to produce the appropriate level of fill.

Weld logic 175 may also generate the fill plan. Generation of the fill plan may include determining or indicating one or more welding parameters for each pass (e.g., each bead) of the fill plan. In some implementations, the one or more welding parameters for a pass may indicate a value of the one or more welding parameters at each of multiple waypoints 172 associated with seam 144. After the fill plan is generated, weld logic 175 may generate weld instructions 176 based on the fill plan. Additionally, or alternatively, controller 152 may generate control information 182 based on weld instructions 176. Weld logic 175 may transmit weld instructions 176, control information 182, or a combination thereof to robot 123.

In some implementations, weld logic 175 may use gap information (e.g., seam information 155, such as a gap size or gap variability) to generate or optimize one or more operations associated with weld instructions 176. For example, weld logic 175 may be configured to generate or adapt the weld instructions 176 and/or motion parameters 156 dynamically (e.g., welding voltage) based on the width/size of the gap. For example, the dynamically adjusted welding instructions for robot 123 can result in precise welding of the seam at variable gaps. Adjusting the welding instructions, such as weld instruction 176, may include adjusting a welder voltage, a welder current, a duration of an electrical pulse, a shape of an electrical pulse, a material feed rate, or a combination thereof. Additionally, or alternatively, adjusting motion parameters 156 may include adjusting motion of manufacturing tool 126 (e.g., weld head) to include different weaving patterns, such as convex weave, concave weave, etc. to weld a seam having a variable gap.

Machine learning logic 107 is configured to learn from and adapt to a result based on one or more operations. For example, the one or more operations may include a welding operation, an image capture operation, a parameter (e.g., light source parameter 153 or imaging parameter 154) generation operation, a light source operation, a seam location operation, a gap operation, an object or weld detection operation, or a combination thereof. During or based on operation of system 100, a machine learning logic (e.g., machine learning logic 107) is provided with sensor data 180, 165, image data, parameter data (e.g., 153, 154, 156), other information (164), or a combination thereof. In some implementations, machine learning logic 107 is configured to update a model or an algorithm.

As noted above, robot 123 may be configured to tack weld the objects 135 and 136 in a desired configuration in workspace 130. The desired configuration may be determined by control system 110 using a CAD model stored in design 170. The CAD model may include a model showing objects 135 and 136 in their welded state. In some implementations, the same CAD model (or a different CAD model including models of the objects 135 and 136 not in their welded state) may include annotations (e.g., user annotated) indicating potential positions along the unwelded seam 144 where tack welds can be applied. In some implementations, machine learning logic 107 may include logic that is to determine optimal locations for tack welds based on one of the above-described CAD models. For example, machine learning logic 107 could be trained by exposing it to a vast dataset of successful tack welding scenarios. By leveraging this data, the logic may be configured to learn and adapt to predict the best locations for tack welds using the CAD models of the objects that are to be tack welded, optimizing assembly efficiency and structural integrity of the final configuration. Furthermore, machine learning logic 107 may also utilize real-time feedback from sensors to dynamically adjust its predictions based on the actual physical conditions of objects 135 and 136.

In some implementations, machine learning logic 107 is configured to train a neural network to be used by image processing logic 177 (e.g., seam localization logic 178). The neural network may be trained using one or more images associated with a non-ideal relative pose between seam 144 and light source 128 and/or camera 121. In some implementations, the non-ideal relative pose may be a result of reliance by artificial light 173 and/or image capture logic 174 on an estimated position of seam 144 based on a CAD model. For example, in some situations, an actual position of seam 144 may deviate from the estimated position and therefore, a position or pose of light source 128 and/or camera 121 may be less than ideal. Training the neural network with one or more images associated with a non-ideal relative pose between seam 144 and light source 128 and/or camera 121 may enable image processing logic 177 (e.g., seam localization logic 178) to improve accuracy of detection of a gap associated with seam 114.

Sensor data 165 may include or correspond to the sensor data 180 received by controller 152. Pose information 166 may include or correspond to a pose of first object 135, second object 136, or a combination thereof. Additionally, or alternatively, pose information may include, correspond to, or indicate a pose or frame of reference of light source 128, a pose or frame of reference of manufacturing tool 126, a pose or frame of reference of camera 121, a pose or frame of reference of positioner 127, or a combination thereof.

System information 168 may include information associated with one or more devices (e.g., robot 123, manufacturing tool 126, or sensor 109). To illustrate, system information 168 may include ID information, a communication address, one or more parameters, or a combination thereof, as illustrative, non-limiting examples. Additionally, or alternatively, system information 168 may include or indicate a location (e.g., of seam 144), a path plan, a motion plan, a work angle, a tip position, or other information associated with movement of robot 123, a voltage, a current, a feed rate, or other information associated with a weld operation, or a combination thereof.

Design 170 may include or indicate a CAD model of one or more parts/objects, such as first object 135, second object 136, or a combination thereof. In some implementations, the CAD model may be annotated with or indicate one or more weld parameters, a geometry or shape of a weld, a geometry or shape of a seam, dimensions, tolerances, one or more object parameters (e.g., material type), other information, or a combination thereof. Point cloud 169 may include a set of points each of which represents a location in 3D space of a point on a surface of a part (e.g., 135 or 136) and/or positioner 127.

Light source parameters 153 include an angle of incidence of emitted light from light source 128 relative to an object, such as a surface of first object 135 or second object 136. Additionally, or alternatively, light source parameters 153 include a pose of light source 128, a wavelength or color of the emitted light, a luminosity of the emitted light, a pattern of the emitted light, a duration or exposure of the emitted light, or a combination thereof.

Imaging parameters 154 include one or more imaging parameters associated with the one or more cameras—e.g., one or more image capture parameters. The one or more image capture parameters may be associated with or correspond to camera 121. For example, the one or more image capture parameters may include or correspond to a camera pose, an aperture size, a focal length, an exposure time, or a combination thereof. In some implementations, imaging parameters 154 may be determined based on the CAD model (e.g., 170), one or more light source parameters 153, or a combination thereof. For example, imaging parameters 154 may be determined to enable camera 121 to perform an image capture operation during operation of light source 128 based on light source parameters 153. In some implementations, imaging parameters 154 may include light source parameters 153.

Seam information 155 includes or indicates a position, an orientation, or a combination thereof, of seam 144. The terms “position” and “orientation” are spelled out as separate entities in the disclosure above. However, the term “position” when used in context of a part/object means “a particular way in which a part is placed or arranged.” The term “position” when used in context of a seam means “a particular way in which a seam on the part is positioned or oriented.” As such, the position of the part/seam may inherently account for the orientation of the part/seam. As such, “position” can include “orientation.” For example, position can include the relative physical position or direction (e.g., angle) of a part or seam.

One or more waypoints 172 may include, indicate, or correspond to a location along seam 144. In some implementations, seam information 155 includes or indicates waypoints 172. The one or more waypoints may include a set of waypoints determined by discretizing seam 144. Each waypoint of the set of waypoints can be configured to constrain an orientation of the weld head of a welding robot (e.g., welding robot 123) in three or more degrees of freedom. For example, each waypoint may restrict the motion and/or orientation of the weld head along three translational axes and two rotational axes (e.g., fixing the position and weld angle).

Motion parameters 156 may be configured to instruct robot 123, manufacturing tool 126, or camera 121 to move near a position of seam 144. For example, motion parameters 156 may instruct robot 123 to move manufacturing tool 126 to thereby align manufacturing tool 126 for performance of a welding operation.

Weld fill plan 157 indicates one or more fill parameters, one or more weld bead parameters (e.g., one or more weld bead profiles), or a combination thereof. The one or more fill parameters may include or indicate a number of beads, a sequence of beads, a number of layers, a fill area, a cover profile shape, a weld size, or a combination thereof, as illustrative, non-limiting examples. The one or more weld bead parameters may include or indicate a bead size (e.g., a height, width, or distribution, a bead spatial property (e.g., a bead origin or a bead orientation), or a combination thereof, as illustrative, non-limiting examples. Additionally, or alternatively, weld fill plan 157 may include or indicate one or more welding parameters for forming one or more weld beads. The one or more welding parameters may include or indicate a wire feed speed, a travel speed, a travel angle, a work angle (e.g., torch angle), a weld mode (e.g., a waveform), a welding technique (e.g., TIG or MIG), a voltage or current, a contact tip to work distance (CTWD) offset, a weave or motion parameter (e.g., a weave type, a weave amplitude characteristic, a weave frequency characteristic, or a phase lag), a wire property (a wire diameter or a wire type—composition/material), a gas mixture, a heat input, or a combination thereof, as illustrative, non-limiting examples.

Weld fill plan 157 may be generated based on one or more weld profiles (e.g., a cross-sectional weld profile), one or more bead models, one or more contextual variables, or a combination thereof. In some implementations, the weld profile may include or indicate a cross-section of seam 144, such as a cross-section of seam 144 that includes weld material—e.g., one or more layers of weld material. The weld profile may correspond to a waypoint of one or more waypoints 172. The bead model may be configured to model an interaction of a bead weld placed on a surface. For example, the bead model may indicate a resulting bead profile or cross-sectional area of a bead weld placed on the surface. In some implementations, the one or more contextual variables include or indicate gravity, surface tension, gaps, tacks, surface features, joint features, part material properties or dimensions, or a combination thereof.

Communications adapter 104 is configured to couple control system 110 to a network (e.g., a cellular communication network, a LAN, WAN, the Internet, etc.). Communications adapter 104 of embodiments may, for example, comprise a WiFi network adaptor, a Bluetooth interface, a cellular communication interface, a mesh network interface (e.g., ZigBee, Z-Wave, etc.), a network interface card (NIC), and/or the like. User interface adapter and display adapter 106 of the illustrated embodiment may be utilized to facilitate user interaction with control system 110. For example, user interface and display adapter 106 may couple one or more user input devices (e.g., keyboard, pointing device, touch pad, microphone, etc.) to control system 110 for facilitating user input when desired (e.g., when gathering information regarding one or more weld parameters).

In some implementations, I/O and communication adapter 104 may also couple sensor(s) 109 (e.g., global sensor, local sensor, etc.) to processor 101 and memory 102, such as for use with respect to the system detecting and otherwise determining a seam location. I/O and communication adapter 104 may additionally or alternatively provide coupling of various other devices, such as a printer (e.g., dot matrix printer, laser printer, inkjet printer, thermal printer, etc.), to facilitate desired functionality (e.g., allow the system to print paper copies of information such as planned trajectories, results of learning operations, and/or other information and documents).

User interface and display adapter 106 may be configured to couple one or more user output devices (e.g., flat panel display, touch screen, heads-up display, holographic projector, etc.) to control system 110 for facilitating user output (e.g., simulation of a weld) when desired. It should be appreciated that various ones of the foregoing functional aspects of control system 110 may be included or omitted, as desired or determined to be appropriate, depending upon the specific implementation of a particular instance of system 100.

User interface and display adapter 106 is configured to be coupled to storage device 108, another device, or a combination thereof. Storage device 108 may include one or more of a hard drive, optical drive, solid state drive, or one or more databases. Storage device 108 may be configured to be coupled to controller 152, processor 101, or memory 102, such as to exchange program code for performing or techniques described here, at least with reference to instructions 103. Storage device 108 may include a random access memory (RAM), a memory buffer, a hard drive, an erasable programmable read-only memory (EPROM), an electrically erasable read-only memory (EEPROM), a read-only memory (ROM), Flash memory, and the like. Storage device 108 may include or correspond to memory 102.

In some implementations, storage device 108 includes a database 112 and executable code 113. Controller 152 may interact with database 112, for example, by storing data to database 112 and/or retrieving data from database 112. Although described as database 112 being in storage device 108, in other implementations, database 112 may be stored on a cloud-based platform. Database 112 may store any information useful to the system 100 in performing welding operations. For example, database 112 may store a CAD model (e.g., 170) of one or more parts (e.g., 135, 136). Additionally, or alternatively, database 112 may store an annotated version of a CAD model of one or more parts (e.g., 135, 136). Database 112 may also store a point cloud of the one or more parts generated using the CAD model (also herein referred to as CAD model point cloud). Similarly, welding instructions (e.g., 176) for one or more parts that are generated based on 3D representations of the one or more parts and/or on user input provided regarding one or more parts (e.g., regarding which seams of the part to weld, welding parameters, etc.) may be stored in database 112.

In some implementations, executable code 113 may when executed, causes controller 152 to perform one or more actions attributed herein to controller 152, or, more generally, to the system 100. Executable code 113 may include a single, self-contained, program. Additionally, or alternatively executable code 113 may be a program having one or more function calls to other executable code which may be stored in storage device 108 or elsewhere, such as cloud storage or memory 102, as illustrative, non-limiting examples. In some examples, one or more functions attributed to execution of executable code 113 may be implemented by hardware. For instance, multiple processors may be useful to perform one or more discrete tasks of the executable code 113.

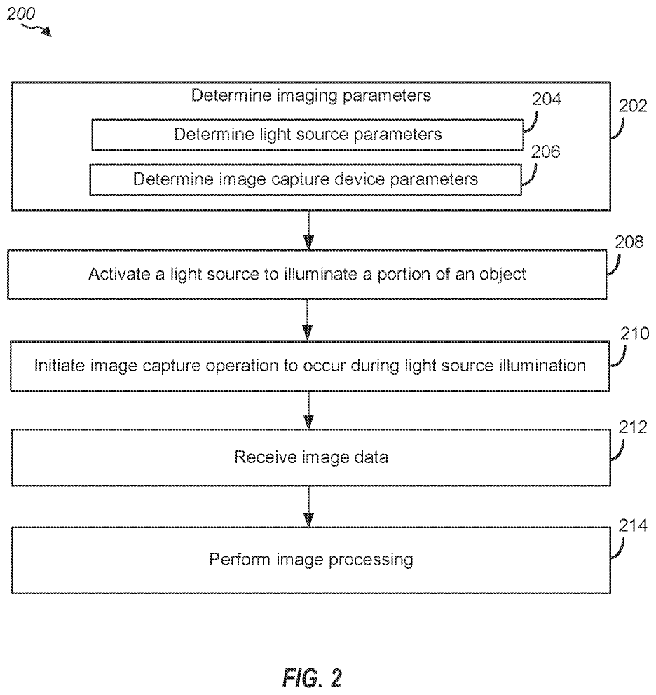

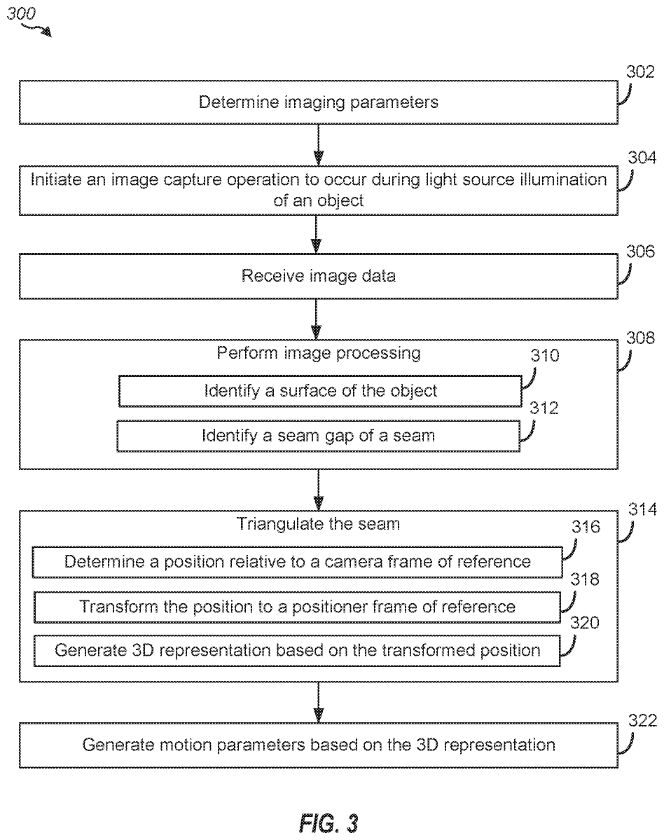

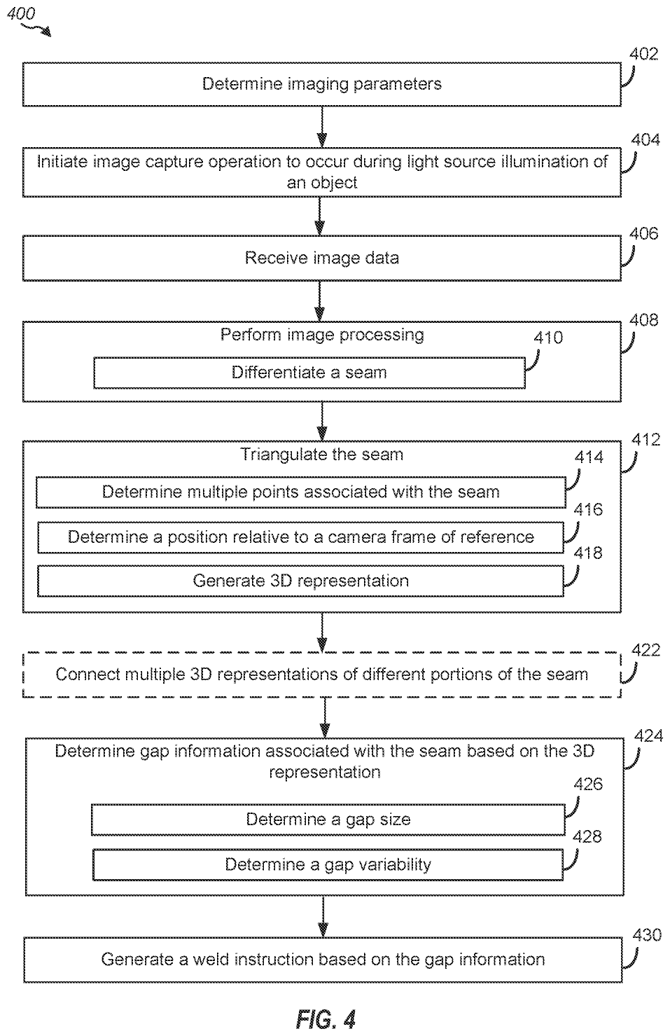

During operation of system 100, controller 152 may perform one or more techniques associated with seam localization and/or seam gap measurement. For example, controller 152 may perform an artificial light-based seam technique as described further herein at least with reference to FIG. 2, an artificial light-based seam localization technique as described further herein at least with reference to FIG. 3, an artificial light-based gap measurement technique as described further herein at least with reference to FIG. 4, or a combination thereof.

In some implementations, controller 152 is configured to control light source 128 emit light (e.g., of defined and/or controlled wavelength) at weldable objects, such as first object 135, second object 136, or both. When the light is incident on the weldable objects, controller 152 may initiate camera 121 to capture images (e.g., 165, 180) of the weldable objects. Controller 152 may process the images to localize a gap, such as one or more weldable seams (e.g., 144), formed between weldable objects. Additionally, or alternatively, controller 152 may process the images to identify one or more features of the weldable objects, such as the tack welds that may be used to arrange the weldable objects in a desired configuration. Following the identification of the location, position, or orientation, (or a combination thereof) of a gap, such as unwelded seam 144, controller 152 may control robot 123 may perform a welding operation, such as a tack welding operation or a lay welding operation to lay weld material in seam 144 to form a joint.

In some implementations, controller 152 is configured to process the images to determine seam information. The seam information may include a gap measurement and/or seam gap variability along the length of a gap, such as a weldable seam. In some implementations, controller 152 may determine, based on the seam information, whether or not two objects are positioned within a threshold range of each other. If the two objects are not within the threshold range, controller 152 may generate one or more instructions to adjust a position of at least one of the objects. In some implementations, after the adjustment, controller 152 may initiate a scanning or image capture operation and may determine updated seam information based on the scanning or image capture operation to confirm that the two objects are positioned within the threshold range of each other. Additionally, or alternatively, controller 152 may also be configured to dynamically adapt welding operation based on the seam information, such as determined seam gap variability. For example, controller 152 may be configured to determine a location to form a former weld (e.g., a tack weld) and may generate and send instructions to form the former weld at the location. Additionally, or alternatively, controller 152 may generate or update a weld plan based on the seam information. Controller 152 may also generate based on the weld plan and send instructions to robot 123 for execution.

In some implementations, controller 152 is configured to perform an artificial light-based seam technique. For example, controller 152 is configured to generate instructions (e.g., 176, 182) for a welding robotic system (e.g., 100, 110) by a robot controller (e.g., 110, 152, or 101) of a welding robot (e.g., 123). To illustrate, controller 152 is configured to receive a CAD model (e.g., 170) including a representation of first object 135 and second object 136 associated with a weldable seam (e.g., 144). Controller 152 is also configured to determine, based on the CAD model, one or more light source parameters 153 for controlling light source 128, and control light source 128 to emit light toward, first and second objects 135, 136 positioned to form the weldable seam. Controller 152 is further configured to, during illumination of first object 135, second object 136, or a combination thereof by light source 128, control one or more cameras 121 to capture images (e.g., 165, 180) of first and second objects 135, 136 along a length of the weldable seam. In some implementations, controller 152 is configured to determine, based on the CAD model and/or the light source parameters 153, imaging parameters associated with the one or more cameras 121. Controller 152 is also configured to perform segmentation on the images to identify a gap (e.g., the weldable seam).

In some implementations, controller 152 is configured to perform an artificial light-based seam localization technique. For example, controller 152 is configured to control light source 128 to emit light at/on first object 135, second object 136, or a combination thereof. The first and second objects 135, 136 are positioned to form a gap, such as a weldable seam (e.g., 144). Controller 152 is also configured to, during illumination of the first object 135, the second object 136, or a combination thereof by light source 128, control a camera 121 to capture images (e.g., 180, 165) of first and second objects 135, 136 along a length of the weldable seam (e.g., 144). Controller 152 is further configured to differentiate, within the images, the gap, such as the weldable seam (e.g., 14), from first and second objects 135, 136. In some implementations, controller 152 is configured to triangulate the differentiated weldable seam to identify a position (e.g., seam information 155) of the weldable seam (e.g., 144) relative to a reference point (e.g., pose information 166 or system information 168) associated with the welding tool (e.g., 126), and generate motion parameters 156 for the welding tool to move the welding tool near the identified position of the weldable seam.

In some implementations, controller 152 is configured to perform an artificial light-based gap measurement technique. For example, controller 152 is configured to control light source 128 to emit light at/onto first object 135, second object 136, or a combination thereof. The first and second objects 135, 136 are positioned to form a gap, such as a weldable seam 144. Controller 152 is also configured to, during illumination of the first object 135, the second object 136, or a combination thereof by the light source 128, control one or more cameras 121 to capture images (e.g., 180, 165) of the first and second objects 135, 136 along at least a portion of a length of the gap, such as the weldable seam 144. Controller 152 is further configured to differentiate, in the images, the gap (e.g., the weldable seam 144) from the first and second objects 135, 136, and triangulate the differentiated gap to generate a representation of the gap. The representation may include one or more three-dimensional (3D) representations (e.g., 169) of the gap, such as the weldable seam. In some implementations, controller 152 may triangulate the differentiated seam to identify a position of the seam relative to a reference point (e.g., a point of reference). Controller 152 may be configured to determine, based on the representations, gap information (e.g., seam information 155) along the portion of gap (e.g., the weldable seam 144). In some implementations, controller 152 is configured to generate one or more instructions based on the gap information. For example, controller 152 may generate one or more motion instructions to adjust a position of at least one object. Additionally, or alternatively, controller 152 may generate, based on the gap information, welding instructions 176 for a welding tool (e.g., 126) coupled to robot 123.

As described with reference to FIG. 4, the present disclosure provides techniques for supporting artificial light usage, seam localization, gap detection, or a combination thereof. The techniques described improve identification of weldable seams between the weldable objects. For example, use of light source 128 (e.g., an artificial light source) may improve contrast in one or more images and improve identification of weldable objects, weldable seams, or both. Use of light source during an image capture operation may nullify the impact of ambient light, simplifying seam localization and gap detection. Further, determining or calculating light source parameters 153 to control a lighting scenario may be performed before the image capturing process begins, which may save time and computational resources. Additionally, by determining or adjusting imaging parameters 154 and/or light source parameters 153 (e.g., angle of incidence of light by controlling the pose of light source 128), a strong contrast between the seam and the weldable objects, which may aid machine learning algorithms, such as neural networks, in accurately identifying and locating the seam, as well as, detecting a gap along a length of the seam. Improved seam localization, gap measurement, or both, may also improve positioning of manufacturing tool 126 with respect to objects 135, 136, improve weld planning and/or weld quality, reduce weld time, or a combination thereof.

Referring to FIG. 2, FIG. 2 is a flow diagram illustrating an example process 200 of an artificial light-based seam technique in a robotic manufacturing environment according to one or more aspects. For example, the robotic manufacturing environment may include or correspond to system 100. In some implementations, the robotic manufacturing environment includes a welding robot, one or more cameras, and the controller. The welding robot may include or correspond to robot 123. A welding tool may be coupled to the welding robot. The welding tool may include or correspond to manufacturing tool 126. The one or more cameras may include or correspond to camera 121. Operations of process 200 may be performed by a control system or a controller (referred to collectively as “the controller” with reference to FIG. 2), such as control system 110, controller 152, or processor 101. For example, example operations (also referred to as “blocks”) of process 200 may enable a controller to perform an artificial light-based seam technique.

In block 202, the controller determines imaging parameters. The imaging parameters may include or correspond to imaging parameters 154, light source parameters 153, image capture device parameters, or a combination thereof. For example, to determine the imaging parameters, the controller may determine light source parameters, at block 204, determine image capture device parameters, at block 206, or a combination thereof. To determine the light source parameters (e.g., 153), the controller may be configured to execute artificial light logic 173. Additionally, or alternatively, to determine the image capture device parameters (e.g., 154), the controller may be configured to execute the image capture logic 174.

In some implementations, the controller may determine the imaging parameters based on a CAD model, such as design 170. The CAD model may include a representation a first object and a second object associated with or that define a weldable seam. For example, the first object and the second object may include or correspond to first object 135, and second object 136, respectively. The weldable seam, such as an unwelded seam, may include or correspond to seam 144. In some implementations, the controller determines, based on the CAD model, one or more light source parameters (e.g., 153) for controlling a light source. For example, the light source may include or correspond to light source 128.

In block 208, the controller activates a light source to illuminate a portion of an object. To illustrate, the controller may activate the light source based on the imaging parameters 154, the light source parameters 153, or a combination thereof. To activate the light source, the controller may be configured to execute artificial light logic 173. The light source may include or correspond to light source 128. The object may include or correspond to first object 135 or second object 136. In some implementations, the controller may control the light source to emit light at the first object and the second object, which are positioned to form a weldable seam. For example, the controller may control the light source to emit a first light on a surface of the first object and emit a second light on a surface of the second object. The first light may have a first characteristic (e.g., a first set of light source parameters) and the second light may have a second characteristic (e.g., a second set of light source parameters) that is different from the first characteristic.

In block 210, the controller initiates or controls an image capture device to perform an image capture operation during light source illumination (e.g., emission of the light by the light source). For example, the image capture device may include or correspond to camera 121. To initiate or control the image capture device, the controller may be configured to execute image capture logic 174. To illustrate, during illumination of the first object, the second object, or a combination thereof, by the light source, the controller may control one or more cameras to capture images of the first and second objects along at least a portion of a length of the weldable seam. Additionally, or alternatively, the controller may control the image capture device based on imaging parameters 154, one or more image capture device parameters, or a combination thereof. In some implementations, the image capture device includes a stereoscopic camera or a camera configured in a stereoscopic configuration.

In block 212, the controller receives image data. For example, the controller may receive the image data from the image capture device. The image data may include or correspond to the images captured by the image capture device, sensor data 180, sensor data 165, or a combination thereof. In some implementations, the image data include 2D image data. To receive the image data, the controller may be configured to execute image processing logic 177.

In block 214, the controller performs image processing. For example, the controller may perform the image processing on the received image data. To perform the image processing, the controller may be configured to execute image processing logic 177, seam localization logic 178, seam gap logic 179, or a combination thereof. In some implementations, the performing the image processing may include performing segmentation on the image data (e.g., the images) to identify the weldable seam. For example, the segmentation may be performed on the image data to differentiate, within the images, the weldable seam from the first and second objects.

In some implementations, the controller may be configured to perform seam identification/detection or seam localization, prior to block 202, to identify the weldable seam (e.g., 144). To perform seam identification/detection or seam localization, the controller may execute image processing logic 177 or seam localization logic 178. Based on identification of the seam, the controller may generate multiple waypoints (e.g., 172) along the weldable seam based on a 3D representation of the weldable seam. The multiple waypoints may include a set of points. The controller may control one or more image capture devices to capture images of the first and second objects along at least a portion of the length of the weldable seam, where the portion is associated with or corresponds to the set of points.

Additionally, or alternatively, the controller may be configured to perform seam identification/detection or seam localization, in block 214 or after one or more operations performed in block 214, to identify the weldable seam (e.g., 144). The controller may triangulate the differentiated weldable seam to identify a position of the weldable seam relative to a reference point. For example, the point of reference may be associated with a welding tool coupled to the welding robot. The position of the weldable seam may include or correspond to seam information 155. The welding tool and the welding robot may include or correspond to manufacturing tool 126 and robot 123, respectively. The controller may generate, based on the position of the weldable seam, motion parameters for the welding tool to move the welding tool near the identified position of the weldable seam. The motion parameters may include or correspond to motion parameters 156. To generate the motion parameters, the controller may be configured to execute path planning logic 105. The motion parameters may be configured to instruct the welding tool to move near the identified position of the unwelded seam to thereby align the welding tool for performance of a welding operation.

In some implementation, the controller may determine or generate gap information, in block 214 or after one or more operations performed in block 214. The gap information may include or correspond to seam information 155, such as a gap size, gap variation, or a combination thereof. To determine the gap information, the controller may be configured to execute image processing logic 177, seam gap logic 179, or a combination thereof. To further illustrate, to determine the gap information, the controller triangulates the differentiated weldable seam to generate one or more 3D representations (e.g., 169) of the weldable seam. Based on the one or more 3D representations, the controller generates the gap information along at least at a portion of the weldable seam. In some implementations, based on the gap information, the controller generates welding instructions for a welding tool coupled to the welding robot. The welding instructions include or correspond to weld instructions 176. To generate the welding instructions, the controller may be configured to execute weld logic 175.

Referring to FIG. 3, FIG. 3 is a flow diagram illustrating an example process 300 of an artificial light-based seam localization technique in a robotic manufacturing environment according to one or more aspects. For example, the robotic manufacturing environment may include or correspond to system 100. In some implementations, the robotic manufacturing environment includes a welding robot, one or more cameras, and the controller. The welding robot may include or correspond to robot 123. A welding tool may be coupled to the welding robot. The welding tool may include or correspond to manufacturing tool 126. The one or more cameras may include or correspond to camera 121. Operations of process 300 may be performed by a control system or a controller (referred to collectively as “the controller” with reference to FIG. 3), such as control system 110, controller 152, or processor 101. For example, example operations (also referred to as “blocks”) of process 300 may enable a controller to perform an artificial light-based seam localization technique. In some implementations, to perform the artificial light-based seam localization technique, the controller may already know the pose information (e.g., location and orientation) of a seam (e.g., 144) within a workspace (e.g., 130) (or between weldable objects—e.g., 135 and 136). The pose information of the seam may include or correspond to pose information 166, seam information 155, or a combination thereof.

In block 302, the controller determines imaging parameters. In block 202, the controller determines imaging parameters. The imaging parameters may include or correspond to imaging parameters 154, light source parameters 153, image capture device parameters, or a combination thereof. To determine the imaging parameters, the controller may perform one or more operations as described with reference to block 202 of FIG. 2.

In block 304, the controller initiates or controls an image capture operation to occur during light source illumination of an object. For example, while the object is illuminated by the light source, the controller may control the image capture device to capture images of the object along a weldable seam. In some implementations, the images may be captured relative to a frame of reference of the image capture device (e.g., camera 121). The object may include or correspond to first object 135 or second object 136. To initiate or control the image capture operation, the controller may perform one or more operations as described with reference to block 210 of FIG. 2. Additionally, or alternatively, to initiate or control the image capture operation, the controller may be configured to execute image capture logic 174. The image capture operation may be performed by an image capture device, such as camera 121. The camera may include a stereoscopic camera, the stereoscopic camera including a first camera and a second camera arranged in a stereo configuration. The images may include a first image captured by the first camera and a second image captured by the second camera. The first image and the second image may be captured relative to a frame of reference of the stereoscopic camera.

The light source illumination may be performed by a light source, such as light source 128. In some implementations, the controller activates the light source to illuminate at least a portion of the object. To activate or control the light source, the controller may perform one or more operations as described with reference to block 208 of FIG. 2. For example, the controller may control the light source to emit light at the object that is to be welded. Control of light source may include control of imaging parameters 154 or light source parameters 153, such as exposure and pose of the light source—i.e., an angle of incidence of the light.

In block 306, the controller receives image data. To receive the image data, the controller may perform one or more operations as described with reference to block 212 of FIG. 2.

In block 308, the controller performs image processing. For example, the controller may perform the image processing on the received image data. To perform the image processing, the controller may be configured to execute image processing logic 177, seam localization logic 178, seam gap logic 179, or a combination thereof. In some implementations, the performing the image processing may include performing segmentation on the image data (e.g., the images) to identify the weldable seam. For example, the segmentation may be performed on the image data to differentiate, within the images, the weldable seam from the first and second objects.

In some implementations, to perform the image processing, the controller may identify a surface of the object, at block 310, identify a gap of the seam, at block 312, or a combination thereof. To identify the seam gap, the controller may differentiate, within the images (e.g., the received image data), the weldable seam from the first and second objects. To identify the surface, the controller may be configured to execute image processing logic 177. Additionally, or alternatively, to identify the seam gap, the controller may be configured to execute image processing logic 177, seam gap logic 179, or a combination thereof.

In block 314, the controller triangulates the seam. For example, the controller may triangulate the differentiated weldable seam to identify a position of the weldable seam relative to a reference point, such as a reference point associated with a welding tool (e.g., 126), a reference point associated with an image capture device (e.g., 121), a reference point associated with a positioner (e.g., 127), or a combination thereof. In some implementations, triangulation of the differentiated weldable seam is performed relative to the frame of reference of the camera. For example, the position of the weldable seam may be identified relative to a frame of reference associated with a positioner device. The frame of reference of the camera may be different from the frame of reference associated with the positioner device. To triangulate the seam, the controller may be configured to execute the image processing logic 177, the seam localization logic 178, or a combination thereof. In some implementations, to triangulate the seam, the controller may determine a position (of the seam) relative to a frame of reference (e.g., a camera frame of reference), at block 316, transform the position to a positioner frame of reference, at block 318, generate a 3D representation based on the transformed position, at block 320, or a combination thereof. The 3D representation may include or correspond to point cloud 169.

In block 322, the controller generates motion parameters based on the 3D representation. The motion parameters may include or correspond to motion parameters 156. The motion parameter may be configured to instruct the welding tool to move near the identified position of the unwelded seam to thereby align the welding tool for performance of a welding operation or other operation. To generate the motion parameters, the controller may be configured to execute path planning logic 105. In some other implementations, in addition to, or as an alternative to, generation of the motion parameters to move the welding tool, the controller may generate one or more instructions to adjust a position of at least one object.

Referring to FIG. 4, FIG. 4 is a flow diagram illustrating an example process 400 of an artificial light-based gap measurement technique in a robotic manufacturing environment according to one or more aspects. For example, the robotic manufacturing environment may include or correspond to system 100. In some implementations, the robotic manufacturing environment includes a welding robot, one or more cameras, and the controller. The welding robot may include or correspond to robot 123. A welding tool may be coupled to the welding robot. The welding tool may include or correspond to manufacturing tool 126. The one or more cameras may include or correspond to camera 121. Operations of process 400 may be performed by a control system or a controller (referred to collectively as “the controller” with reference to FIG. 4), such as control system 110, controller 152, or processor 101. For example, example operations (also referred to as “blocks”) of process 400 may enable a controller to perform an artificial light-based gap measurement technique. In some implementations, an artificial light-based seam localization technique, such as process 300, may be performed prior to or as part of process 400. For example, a 3D representation (e.g., 169) associated with a seam, one or more waypoints 172 associated with the seam, or a combination thereof may be determined or generated prior to or as part of process 400.

In block 402, the controller determines imaging parameters. To determine the imaging parameters, the controller may perform one or more operations as described with reference to block 202 of FIG. 2 or block 302 of FIG. 3.

In block 404, the controller initiates an image capture operation to occur during light source illumination of an object. To initiate or control the image capture operation, the controller may perform one or more operations as described with reference to block 210 of FIG. 2 or block 304 of FIG. 3. In some implementations, the controller may select a portion of a seam associated with a set of points (e.g., 169 or 172) and may control an image capture device to capture one or more images (e.g., generate image data) of the portion of the seam based on the set of points.

In block 406, the controller receives image data. To receive the image data, the controller may perform one or more operations as described with reference to block 212 of FIG. 2 or block 306 of FIG. 3.

In block 408, the controller performs image processing. For example, the controller may perform the image processing on the received image data. To perform the image processing, the controller may be configured to execute image processing logic 177, seam localization logic 178, or a combination thereof. In some implementations, to receive the image data, the controller may perform one or more operations as described with reference to block 308 of FIG. 3.

To perform the image processing, the controller may differentiate a seam, at block 410. In some implementations, the controller may differentiate, in the images (e.g., the image data), the weldable seam from the first and second objects. In some implementations, the performing the image processing may include performing segmentation on the image data (e.g., the images) to identify the weldable seam. For example, the segmentation may be performed on the image data to differentiate, within the images, the weldable seam from the first and second objects.

In block 412, the controller triangulates the seam. For example, the controller may triangulate the differentiated weldable seam to generate one or more 3D representations of the weldable seam. The 3D representations may include or correspond to point cloud 169. In some implementations, triangulation includes calculating a position of a point (or multiple points along the seam) by measuring angles to the point from a known reference, such as a camera's frame of reference or a positioner's frame of reference.

In some implementations, to triangulate the seam, the controller may determine multiple points associated with the seam, at block 414, determine a position of the seam relative to a frame of reference (e.g., a camera frame of reference), at block 416, generate a representation (e.g., a 2D or a 3D representation), at block 418, or a combination thereof.

In some implementations, the controller may optionally, at block 422, connect multiple 3D representations of different portions of the seam to generate a connected 3D representation. For example, if the controller generates multiple 3D representations—e.g., for different portions of the weldable seam, the controller may connect at least two 3D representations of the multiple 3D representations to generate a connected 3D representation of the weldable seam. In some implementations, the controller connects the at least two 3D representations of the weldable seam using a curve fitting algorithm.

In block 424, the controller determines gap information associated with the seam. The gap information may be determined based on the 3D representation or the connected 3D representation, 2D information, or a combination thereof. The gap information may include or correspond to seam information 155. To determine the gap information, the controller may execute image processing logic 177 or seam gap logic 179. In some implementations, the controller may determine the gap information (along the portion of the weldable seam) based on the one or more 3D representations or the connected 3D representation.

To determine the gap information, the controller may determine a gap size, at block 426, determine a gap variability, at block 428, or a combination thereof. In some implementations, determining the gap information includes determining a gap size at a set of points along the portion of the length of the weldable seam. Additionally, or alternatively, determining the gap variability includes determining the gap variability in in gap sizes at the set of points.

In block 430, the controller generates instructions (e.g., a weld instruction or other instruction) based on the gap information. The welding instructions include or correspond to weld instructions 176. To generate the welding instructions, the controller may be configured to execute weld logic 175. In some implementations, the welding instructions are generated for a welding tool (e.g., 126) coupled to the welding robot (e.g., 123). The other instruction may include an instruction associated with adjusting a position of at least one object, as an illustrative, non-limiting example.

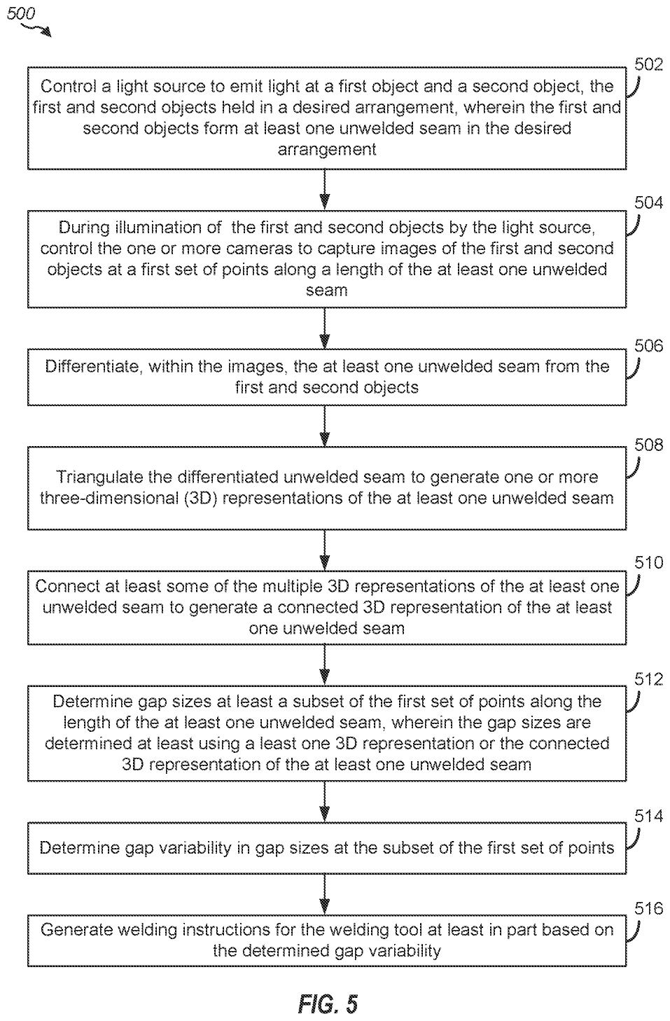

Referring to FIG. 5, FIG. 5 is a flow diagram illustrating an example process 500 of an artificial light-based gap measurement technique in a robotic manufacturing environment according to one or more aspects. For example, the robotic manufacturing environment may include or correspond to system 100. In some implementations, the robotic manufacturing environment includes a welding robot, one or more cameras, and the controller. The welding robot may include or correspond to robot 123. A welding tool may be coupled to the welding robot. The welding tool may include or correspond to manufacturing tool 126. The one or more cameras may include or correspond to camera 121. Operations of process 500 may be performed by a control system or a controller (referred to collectively as “the controller” with reference to FIG. 5), such as control system 110, controller 152, or processor 101. For example, example operations (also referred to as “blocks”) of process 500 may enable a controller to perform an artificial light-based gap measurement technique.

In block 502, the controller controls a light source to emit light at a first object and a second object. The light source may include or correspond to light source 128. The first object and the second object may include or correspond to first object 135 and second object 136, respectively.

The first and second objects are held in a desired arrangement and form at least one unwelded seam (e.g., a weldable seam) in the desired arrangement. The unwelded seam may include or correspond to seam 144. In some implementations, the first and second objects are held in the desired arrangement using one or more tack welds, one or more weld joints, or a combination thereof. The one or more tack welds, the one or more weld joints, or a combination thereof may be implemented based on a CAD model (e.g., 170). In some implementations, wherein the one or more tack welds holding the first and second objects in the desired arrangement includes a first tack weld and a second tack weld. In some such implementations, the at least one unwelded seam is between the first tack weld and the second tack weld. Additionally, or alternatively, the first and second objects may be held in the desired arrangement using one or more fixture clamps, such as one or more fixture clamps coupled to or of a positioner, such as positioner 127.

In some implementations, the light source (e.g., 127) is coupled to the robot device, such as robot device (e.g., 120). In other implementations, the robotic manufacturing environment includes a second robot device and the light source is coupled to the second robot device. The controller may be configured to control one or more operations of the robot device, the second robot device, or a combination thereof.

In some implementations, the light source (e.g., 127) may include multiple light sources. In some such implementations, the controller may be configured to control each light source of the multiple light sources. For example, the controller may control a first light source of the multiple light sources based on a first set of light source parameters (e.g., 153) and may control a second light source of the multiple light sources based on a second set of light source parameters (e.g., 153). At least one parameter or parameter value of the first set of light source parameters may be different from the second set of light source parameters. For example, the first set of light source parameters may include or indicate a different wavelength, a different light pattern, a different illumination periodicity, or a combination thereof. In some implementations, the controller may control the light source by executing artificial light logic 173.

In block 504, the controller, during illumination of the first and second objects by the light source, controls the one or more cameras to capture images of the first and second objects at a first set of points along or associated with a length of the at least one unwelded seam. For example, the one or more cameras may include or correspond to camera 121. The images may include or correspond to sensor data 180, sensor data 165, or a combination thereof. In some implementations, the first set of points may include or correspond to one or more points of a 3D representation (e.g., 169), one or more waypoints (e.g., 172), or a combination thereof. In some implementations, the controller may control the one or more cameras by executing image capture logic 174.

In some implementations, the controller may control the cameras to capture a first set of images associated with the first set of points, and to capture a second set of images associated with a second set of points. The first set of points may be different from the second set of points. In some implementations, the first set of points may include at least one point that is also include in the second set of points.

In some implementations, the one or more cameras include at least two cameras arranged in a stereo configuration. For example, the one or more cameras may include a stereoscopic camera, such as a pair of cameras. Alternatively, the one or more cameras may include a single camera which may be controlled by the controller to capture the images in a stereo relationship. In some implementations, the one or more cameras (e.g., the at least two cameras or the single camera) are coupled to the robot device (e.g., 123). Additionally, or alternatively, the light source (e.g., 127) may also be coupled to the robot device.

In block 506, the controller differentiates, within the images, the at least one unwelded seam from the first and second objects. For example, the differentiated unwelded seam may include or correspond to seam information 155. In some implementations, the controller may perform image processing, such as segmentation, on the images to differentiate the unwelded seams. For example, to perform image processing, the controller may execute image processing logic 177, or seam gap logic 179. It is noted that the image processing and/or segmentation techniques may be performed using a trained model or machine learning. For example, machine learning logic 107 may train a model or use a model trained using one or more images in association with light emitted from the light source, one or more light source parameters (e.g., 153), one or more imaging parameters (e.g., 154), information associated with one or more differentiated unwelded seams, or a combination thereof.

In block 508, the controller triangulates the differentiated unwelded seam to generate one or more three-dimensional (3D) representations of the at least one unwelded seam. For example, the one or more 3D representations may include or correspond to point cloud 169. In some implementations, a first 3D representation may include or correspond to the first set of points. Additionally, or alternatively, a second 3D representation may include or correspond to a second set of points along the length of the at least one welded seam. In some implementations, the controller may perform the triangulation for a portion of the length of the seam. To illustrate, the portion may include or correspond to a few centimeters, which may be associated with the first set of points, as an illustrative, non-limiting example. In some implementations, to generate the one or more 3D representations, the controller may execute image processing logic 177.

In block 510, the controller connects at least some of the multiple 3D representations of the at least one unwelded seam to generate a connected 3D representation of the at least one unwelded seam. The connected 3D representation may include or correspond to point cloud 169. For example, two or more generated 3D representations may at least partially overlap and the controller may perform a cure fitting operation between two or more generated 3D representations to connect the 3D representations. It is noted that the connecting operation described with reference to block 510 may be optionally performed. For example, the one or more 3D representations may include a single 3D representation, or a 3D representation of the one or more 3D representations may not be connected with another 3D representation.

In block 512, the controller determines gap sizes at least a subset of the first set of points along the length of the at least one unwelded seam. For example, the gap sizes may include or correspond to seam information 155. The gap sizes may be determined at least using at least one 3D representation (of the one or more 3D representations) or the connected 3D representation of the at least one unwelded seam. In some implementations, to determine the gap sized, the controller may execute seam gap logic 179.

In block 514, the controller determines gap variability in gap sizes at the subset of the first set of points. For example, the gap variability may include or correspond to seam information 155. In some implementations, to determine the gap variability, the controller may execute seam gap logic 179.

In block 516, the controller generates welding instructions for the welding tool at least in part based on the determined gap variability. For example, the welding instructions may include or correspond to weld instructions 176. The welding tool may include or correspond to manufacturing tool 126. In some implementations, to generate the welding instructions, the controller may execute weld logic 175, path planning logic 105, or a combination thereof.

In some implementations, the controller controls the light source to emit light at the first object and the second object by controlling one or more light source parameters. For example, the one or more light source parameters may include or correspond to light source parameters 153. The one or more light source parameters may include an angle of incidence of the emitted light relative to the first object, the second object, or a combination thereof. Additionally, or alternatively, the one or more light source parameters may include a pose of the light source selected from a range of poses, a wavelength, a luminosity, a pattern, or a combination thereof.

In some implementations, the controller determines one or more light source parameters for controlling the light source. For example, the one or more light source parameters may include or correspond to light source parameters 153. The controller may determine the one or more light source parameters based on a CAD model (e.g., 170). For example, to control the light source to emit the light at the first object and the second object, the controller determines and controls an angle of incidence of the emitted light relative to at least one of the two objects. The angle of incidence is determined using a CAD model including a representation of the at least one unwelded seam. For example, the CAD model may include or correspond to design 170. To illustrate, the controller may determine the angle of incidence or the pose of the light source based on the CAD model. For example, the angle of incidence may be determined based on one or more seam normal lines associated with the unwelded seam, based on a normal line associated with a surface of the first object or a surface of the second object, or a combination thereof. In some implementations, the angle of incidence is determined to increase a contrast for between different surfaces included in the images, such as a surface of the first object and a surface of the second object, as an illustrative, non-limiting example. The contrast may include or be associated with a contradiction in luminance or color that makes an object or feature distinguishable. For example, in visual perception of the real world, contrast may be determined by the difference in the color and brightness of the object and other objects within the same field of view. In some implementations, the controller may cause the light source to illuminate the first and second objects with light from the light source bring about a first luminance on a surface of the first object, a second luminance on a surface of the second object, or a combination thereof. The illuminated surfaces of the first object and/or the second object, or the unwelded seam, may be differentiated in the images based on the contrast in the luminance.

In some implementations, the controller may determine the one or more light source parameters using a trained model or machine learning. For example, machine learning logic 107 may train a model or use a model trained using one or more images in association with light emitted from the light source, one or more light source parameters (e.g., 153), one or more imaging parameters (e.g., 154), information associated with one or more differentiated unwelded seams, one or more CAD models (e.g., 170), one or more 3D representations (e.g., 169), or a combination thereof. For example, the model may be trained to determine the one or more light source parameters that, when applied to and used a light source during an image capture operation, improve differentiation of an unwelded seam in an image.

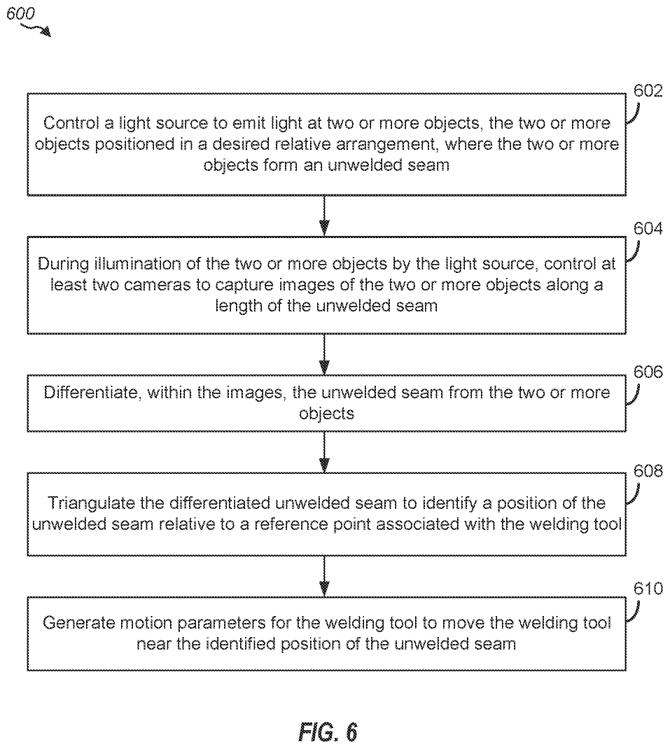

Referring to FIG. 6, FIG. 6 is a flow diagram illustrating an example process 600 of an artificial light-based seam localization technique in a robotic manufacturing environment according to one or more aspects. For example, the robotic manufacturing environment may include or correspond to system 100. In some implementations, the robotic manufacturing environment includes a welding robot, one or more cameras, and the controller. The welding robot may include or correspond to robot 123. A welding tool may be coupled to the welding robot. The welding tool may include or correspond to manufacturing tool 126. The one or more cameras may include or correspond to camera 121. Operations of process 600 may be performed by a control system or a controller (referred to collectively as “the controller” with reference to FIG. 6), such as control system 110, controller 152, or processor 101. For example, example operations (also referred to as “blocks”) of process 600 may enable a controller to perform an artificial light-based seam localization technique.

In block 602, the controller controls a light source to emit light at least two or more objects. The light source may include or correspond to light source 128. The two or more objects may include or correspond to first object 135 and second object 136. The two or more objects are positioned in a desired relative arrangement and form an unwelded seam (e.g., a weldable seam). The unwelded seam may include or correspond to seam 144. In some implementations, operations performed by the controller at block 602 may include or correspond to operations described herein at least with reference to block 502.

In block 604, the controller, during illumination of the two or more objects by the light source, controls at least two cameras to capture images of the two or more objects along a length of the unwelded seam. For example, the at least two cameras may include or correspond to camera 121. The images may include or correspond to sensor data 180, sensor data 165, or a combination thereof. In some implementations, operations performed by the controller at block 604 may include or correspond to operations described herein at least with reference to block 504.

In some implementations, the at least two cameras include at least two cameras arranged in a stereo configuration. For example, the least two cameras may include a stereoscopic camera, such as a pair of cameras. In some such implementations, the images are captured relative to a frame of reference of the at least two cameras, a frame of reference of a welding tool (e.g., 126), or a combination thereof. Although described as two or more cameras, in other implementations, the at least two cameras may be substituted with a single stereoscopic camera or a single camera configured to capture images in a stereo relationship.

In block 606, the controller differentiates, within the images, the unwelded seam from the two or more objects. For example, the differentiated unwelded seam may include or correspond to seam information 155. In some implementations, the controller may perform image processing, such as segmentation, on the images to differentiate the unwelded seams. In some implementations, operations performed by the controller at block 606 may include or correspond to operations described herein at least with reference to block 506.

In block 608, the controller triangulates the differentiated unwelded seam to identify a position of the unwelded seam relative to a reference point, such as a reference point associated with the welding tool (e.g., 126), a reference point associated with the at least two cameras (e.g., 121), a frame of reference of a positioner device (e.g., 127) or a combination thereof. For example, the position of the unwelded seam may include or correspond to seam information 155. In some implementations, to identify the position, the controller may execute image processing logic 177, seam localization logic 178, or a combination thereof.

In some implementations, to identify the position of the unwelded seam relative to the reference point, the controller may perform triangulation relative to the frame of reference of the at least two cameras and may identify the position of the unwelded seam relative to a frame of reference associated with a positioner device present in the workspace. The frame of reference of the at least two cameras may be different from the frame of reference associated with the positioner device. The positioner device may include or correspond to positioner 127. The positioner may be configured to hold, or affix thereto, at least one of the two or more objects in a desired arrangement.

In some implementations, the controller is configured triangulate the differentiated unwelded seam to generate one or more 3D representation of the unwelded seam. The one or more 3D representations may include or correspond to point cloud 160. In some implementations, the one or more 3D representations include multiple 3D representations of the unwelded seam and the controller is configured to connect at least some of the multiple 3D representations of the unwelded seam to generate a connected 3D representation of the at least one unwelded seam. For example, the controller may connect the multiple 3D representations of the unwelded seam using curve fitting algorithms.

The controller may be configured to determine gap information, such as gap size, gap variability, or a combination thereof, along the length of the at least one unwelded seam. The gap information may include or correspond to seam information 155. In some implementations, the gap information (e.g., the gap size or the gap variability) is determined at least using the connected 3D representation of the at least one unwelded seam. The controller may generate welding instructions for the welding tool at least in part based on the determined gap information. For example, the weld instructions. The welding instructions may include or correspond to weld instructions 176.

In block 610, the controller generates motion parameters for the welding tool to move the welding tool near the identified position of the unwelded seam. For example, the motion parameters may include or correspond to motion parameters 156. In some implementations, controller may execute path planning logic 105 to generate the motion parameters.

It is noted that one or more blocks (or operations) described with reference to FIGS. 2-6 may be combined with one or more blocks (or operations) described with reference to another of the figures. For example, one or more blocks (or operations) of FIG. 2 may be combined with one or more blocks (or operations) of FIGS. 3-6. As another example, one or more blocks associated with FIG. 3 may be combined with one or more blocks (or operations) associated with FIGS. 4-6. As another example, one or more blocks associated with FIG. 4 may be combined with one or more blocks (or operations) associated with one or more of FIG. 5 or 6. As another example, one or more blocks associated with FIG. 5 may be combined with one or more blocks (or operations) associated with FIG. 6. Additionally, or alternatively, one or more operations described above with reference to FIG. 1 may be combined with one or more operations described with reference to FIGS. 2-6.

Although aspects of the present application and their advantages have been described in detail, it should be understood that various changes, substitutions and alterations can be made herein without departing from the spirit and scope of the disclosure as defined by the appended claims. Moreover, the scope of the present application is not intended to be limited to the particular implementations of the process, machine, manufacture, composition of matter, means, methods and steps described in the specification. As one of ordinary skill in the art will readily appreciate from the above disclosure, processes, machines, manufacture, compositions of matter, means, methods, or steps, presently existing or later to be developed that perform substantially the same function or achieve substantially the same result as the corresponding implementations described herein may be utilized. Accordingly, the appended claims are intended to include within their scope such processes, machines, manufacture, compositions of matter, means, methods, or steps.

The above specification provides a complete description of the structure and use of illustrative configurations. Although certain configurations have been described above with a certain degree of particularity, or with reference to one or more individual configurations, those skilled in the art could make numerous alterations to the disclosed configurations without departing from the scope of this disclosure. As such, the various illustrative configurations of the methods and systems are not intended to be limited to the particular forms disclosed. Rather, they include all modifications and alternatives falling within the scope of the claims, and configurations other than the one shown may include some or all of the features of the depicted configurations. For example, elements may be omitted or combined as a unitary structure, connections may be substituted, or both. Further, where appropriate, aspects of any of the examples described above may be combined with aspects of any of the other examples described to form further examples having comparable or different properties and/or functions, and addressing the same or different problems. Similarly, it will be understood that the benefits and advantages described above may relate to one configuration or may relate to several configurations. Accordingly, no single implementation described herein should be construed as limiting and implementations of the disclosure may be suitably combined without departing from the teachings of the disclosure.

While various implementations have been described above, it should be understood that they have been presented by way of example only, and not limitation. Although various implementations have been described as having particular features and/or combinations of components, other implementations are possible having a combination of any features and/or components from any of the examples where appropriate as well as additional features and/or components.

Certain features that are described in this specification in the context of separate implementations also can be implemented in combination in a single implementation. Conversely, various features that are described in the context of a single implementation also can be implemented in multiple implementations separately or in any suitable subcombination. Where methods described above indicate certain events occurring in certain order, the ordering of certain events may be modified. Additionally, certain of the events may be performed concurrently in a parallel when possible, as well as performed sequentially as described above.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, some other implementations are within the scope of the following claims. In some cases, the actions recited in the claims can be performed in a different order and still achieve desirable results.

Those of skill in the art would understand that information, message, and signals may be represented using any of a variety of different technologies and techniques. For example, data, instructions, commands, information, and signals that may be referenced throughout the above description may be represented by voltages, currents, electromagnetic waves, magnetic fields or particles, optical fields or particles, or any combination thereof.

Components, the functional blocks, and the modules described herein with the figures include processors, electronics devices, hardware devices, electronics components, logical circuits, memories, software codes, firmware codes, among other examples, or any combination thereof. Software shall be construed broadly to mean instructions, instruction sets, code, code segments, program code, programs, subprograms, software modules, application, software applications, software packages, routines, subroutines, objects, executables, threads of execution, procedures, or functions, among other examples, whether referred to as software, firmware, middleware, microcode, hardware description language or otherwise. In addition, features discussed herein may be implemented via specialized processor circuitry, via executable instructions, or combinations thereof.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. The various illustrative logics, logical blocks, modules, circuits and algorithm processes described in connection with the implementations disclosed herein may be implemented as electronic hardware, computer software, or combinations of both. In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, that is one or more modules of computer program instructions, encoded on a computer storage media for execution by, or to control the operation of, data processing apparatus.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or any conventional processor, controller, microcontroller, or state machine. In some implementations, a processor may be implemented as a combination of computing devices, such as a combination of a DSP and a microprocessor, a plurality of microprocessors, one or more microprocessors in conjunction with a DSP core, or any other such configuration. In some implementations, particular processes and methods may be performed by circuitry that is specific to a given function.

If implemented in software, the functions may be stored on or transmitted over as one or more instructions or code on a computer-readable medium. The processes of a method or algorithm disclosed herein may be implemented in a processor-executable software module which may reside on a computer-readable medium. Computer-readable media includes both computer storage media and communication media including any medium that can be enabled to transfer a computer program from one place to another. A storage media may be any available media that may be accessed by a computer. By way of example, and not limitation, such computer-readable media may include RAM, ROM, EEPROM, CD-ROM or other optical disk storage, magnetic disk storage or other magnetic storage devices, or any other medium that may be used to store desired program code in the form of instructions or data structures and that may be accessed by a computer. Also, any connection can be properly termed a computer-readable medium. Additionally, the operations of a method or algorithm may reside as one or any combination or set of codes and instructions on a machine readable medium and computer-readable medium, which may be incorporated into a computer program product.

Some implementations described herein relate to methods or processing events. It should be understood that such methods or processing events can be computer-implemented. That is, where a method or other events are described herein, it should be understood that they may be performed by a compute device having a processor and a memory. Methods described herein can be performed locally, for example, at a compute device physically co-located with a robot or local computer/controller associated with the robot and/or remotely, such as on a server and/or in the “cloud.”

Memory of a compute device is also referred to as a non-transitory computer-readable medium, which can include instructions or computer code for performing various computer-implemented operations. The computer-readable medium (or processor-readable medium) is non-transitory in the sense that it does not include transitory propagating signals per se (e.g., a propagating electromagnetic wave carrying information on a transmission medium such as space or a cable). The media and computer code (also can be referred to as code) may be those designed and constructed for the specific purpose or purposes. Examples of non-transitory computer-readable media include, but are not limited to: magnetic storage media such as hard disks, floppy disks, and magnetic tape; optical storage media such as Compact Disc/Digital Video Discs (CD/DVDs), Compact Disc-Read Only Memories (CD-ROMs), and holographic devices; magneto-optical storage media such as optical disks; carrier wave signal processing modules, Read-Only Memory (ROM), Random-Access Memory (RAM) and/or the like. One or more processors can be communicatively coupled to the memory and operable to execute the code stored on the non-transitory processor-readable medium. Examples of processors include general purpose processors (e.g., CPUs), Graphical Processing Units, Field Programmable Gate Arrays (FPGAs), Application Specific Integrated Circuits (ASICs), Digital Signal Processor (DSPs), Programmable Logic Devices (PLDs), and the like. Examples of computer code include, but are not limited to, micro-code or micro-instructions, machine instructions, such as produced by a compiler, code used to produce a web service, and files containing higher-level instructions that are executed by a computer using an interpreter. To illustrate, examples may be implemented using imperative programming languages (e.g., C, Fortran, etc.), functional programming languages (Haskell, Erlang, etc.), logical programming languages (e.g., Prolog), object-oriented programming languages (e.g., Java, C++, etc.) or other suitable programming languages and/or development tools. Additional examples of computer code include, but are not limited to, control signals, encrypted code, and compressed code.

As used herein, various terminology is for the purpose of describing particular implementations only and is not intended to be limiting of implementations. For example, as used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). The term “coupled” is defined as connected, although not necessarily directly, and not necessarily mechanically; two items that are “coupled” may be unitary with each other. The terms “a” and “an” are defined as one or more unless this disclosure explicitly requires otherwise.

The term “about” as used herein can allow for a degree of variability in a value or range, for example, within 10%, within 5%, or within 1% of a stated value or of a stated limit of a range, and includes the exact stated value or range. The term “substantially” is defined as largely but not necessarily wholly what is specified (and includes what is specified; e.g., substantially 90 degrees includes 90 degrees and substantially parallel includes parallel), as understood by a person of ordinary skill in the art. In any disclosed implementation, the term “substantially” may be substituted with “within [a percentage] of” what is specified, where the percentage includes 0.1, 1, 5, or 10 percent; and the term “approximately” may be substituted with “within 10 percent of” what is specified. The statement “substantially X to Y” has the same meaning as “substantially X to substantially Y,” unless indicated otherwise. Likewise, the statement “substantially X, Y, or substantially Z” has the same meaning as “substantially X, substantially Y, or substantially Z,” unless indicated otherwise. Unless stated otherwise, the word or as used herein is an inclusive or and is interchangeable with “and/or,” such that when “or” is used in a list of two or more items, means that any one of the listed items can be employed by itself, or any combination of two or more of the listed items can be employed. To illustrate, A, B, and/or C includes: A alone, B alone, C alone, a combination of A and B, a combination of A and C, a combination of B and C, or a combination of A, B, and C. Similarly, the phrase “A, B, C, or a combination thereof” or “A, B, C, or any combination thereof” includes: A alone, B alone, C alone, a combination of A and B, a combination of A and C, a combination of B and C, or a combination of A, B, and C.

Throughout this document, values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “about 0.1% to about 5%” or “about 0.1% to 5%” should be interpreted to include not just about 0.1% to about 5%, but also the individual values (e.g., 1%, 2%, 3%, and 4%) and the sub-ranges (e.g., 0.1% to 0.5%, 1.1% to 2.2%, 3.3% to 4.4%) within the indicated range.

The terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”). As a result, an apparatus that “comprises,” “has,” “includes,” or “contains” one or more elements possesses those one or more elements, but is not limited to possessing only those one or more elements. Likewise, a method that “comprises,” “has,” “includes,” or “contains” one or more steps possesses those one or more steps, but is not limited to possessing only those one or more steps.

Any implementation of any of the systems, methods, and article of manufacture can consist of or consist essentially of—rather than comprise/have/include—any of the described steps, elements, or features. Thus, in any of the claims, the term “consisting of” or “consisting essentially of” can be substituted for any of the open-ended linking verbs recited above, in order to change the scope of a given claim from what it would otherwise be using the open-ended linking verb. Additionally, the term “wherein” may be used interchangeably with “where”.

Further, a device or system that is configured in a certain way is configured in at least that way, but it can also be configured in other ways than those specifically described. The feature or features of one implementation may be applied to other implementations, even though not described or illustrated, unless expressly prohibited by this disclosure or the nature of the implementations.

The claims are not intended to include, and should not be interpreted to include, means-plus- or step-plus-function limitations, unless such a limitation is explicitly recited in a given claim using the phrase(s) “means for” or “step for,” respectively.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure and following claims are not intended to be limited to the examples and designs described herein but is to be accorded the widest scope consistent with the principles and novel features disclosed herein.

1. A method of generating instructions for a welding robot by a robot controller of the welding robot, the method comprising:
controlling a light source to emit light at a first object and a second object, the first and second objects positioned to form a weldable seam, wherein controlling the light source comprises controlling one or more light source parameters including an angle of incidence of the emitted light relative to the first object, the second object, or a combination thereof;
during illumination of the first object, the second object, or a combination thereof by the light source, controlling one or more cameras to capture images of the first and second objects along at least a portion of a length of the weldable seam;
differentiating, in the images, the weldable seam from the first and second objects;
triangulating the differentiated weldable seam to generate one or more three-dimensional (3D) representations of the weldable seam;
determining, based on the one or more 3D representations, gap information along the portion of the weldable seam; and
generating, based on the gap information, welding instructions for a welding tool coupled to the welding robot.

2. The method of claim 1, wherein:
determining the gap information includes:
determining a gap size at a set of points along the portion of the length of the weldable seam; and
determining gap variability in gap sizes at the set of points; and
generating welding instructions include generating the welding instructions based on the determined gap variability.

3. The method of claim 1, wherein:
the one or more 3D representations include multiple 3D representations of portions of the weldable seam; and
further comprising connecting at least two 3D representations of the multiple 3D representations to generate a connected 3D representation of the weldable seam; and
wherein a gap size is determined based on the connected 3D representation.

4. The method of claim 3, wherein connecting the at least two 3D representations of the weldable seam includes using a curve fitting algorithm to connect the at least two 3D representations.

5. The method of claim 1,
wherein the angle of incidence is determined based on a computer aided design (CAD) model including a representation of the weldable seam.

6. The method of claim 1, wherein
the lighting parameters further comprise at least one of:
a pose of the light source;
a wavelength of the emitted light;
a luminosity of the emitted light;
a pattern of the emitted light; or
a duration of the emitted light.

7. The method of claim 1, wherein controlling the light source to emit the light at the first object and the second object includes controlling the light source to emit:
a first light on a surface of the first object, the first light having a first characteristic; and
a second light on a surface of the second object, the second light having a second characteristic that is different from the first characteristic.

8. A welding robotic system comprising:
a robot device positioned in a workspace;
a welding tool coupled to the robotic device, the welding tool configured to weld a first object and a second object positioned in the workspace;
a light source coupled to the robotic device; and
a camera coupled to the robotic device and configured to generate image data associated with the workspace;
a robot controller configured to:
control the light source to emit light at the first object and the second object, the first and second objects positioned to form a weldable seam, wherein controlling the light source to emit the light at the first object and the second object includes controlling the light source to emit a first light on a surface of the first object, the first light having a first characteristic, and a second light on a surface of the second object, the second light having a second characteristic that is different from the first characteristic;
during illumination of the first object, the second object, or a combination thereof by the light source, control the camera to capture images of the first and second objects along at least a portion of a length of the weldable seam;
differentiate, in the images, the weldable seam from the first and second objects;
triangulate the differentiated weldable seam to generate one or more three-dimensional (3D) representations of the weldable seam;
determine, based on the one or more 3D representations, gap information along the portion of the weldable seam; and
generate welding instructions for the welding tool based on the gap information.

9. The welding robotic system of claim 8, wherein:
the camera includes a stereoscopic camera;
the light source is coupled to the robot device; or
a combination thereof.

10. The welding robotic system of claim 8, wherein the first and second objects positioned to form the weldable seam are held in a desired arrangement by one or more tack welds.

11. The welding robotic system of claim 10, wherein:
the one or more tack welds holding the first and second objects in the desired arrangement includes a first tack weld and a second tack weld, and
the weldable seam is between the first tack weld and the second tack weld.

12. The welding robotic system of claim 8, further comprising:
a second robot device coupled to and configured to be controlled by the robot controller, wherein the light source is coupled to the second robot device;
a positioner including one or more fixture clamps configured to hold the first and second objects in a desired arrangement; or
a combination thereof.

13. A welding robotic system comprising:
a robot device positioned in a workspace;
a welding tool coupled to the robotic device, the welding tool configured to weld a first object and a second object positioned in the workspace;
a light source coupled to the robotic device; and
a camera coupled to the robotic device and configured to generate image data associated with the workspace;
a robot controller configured to:
control the light source to emit light at the first object and the second object, the first and second objects positioned to form a weldable seam, wherein controlling the light source to emit the light at the first object and the second object includes controlling lighting parameters comprising an angle of incidence of the emitted light relative to the first object, the second object, or a combination thereof, and at least one of a pose of the light source, a wavelength of the emitted light, a luminosity of the emitted light, a pattern of the emitted light, or a duration of the emitted light;
during illumination of the first object, the second object, or a combination thereof by the light source, control the camera to capture images of the first and second objects along a length of the weldable seam;
differentiate, within the images, the weldable seam from the first and second objects;
triangulate the differentiated weldable seam to identify a position of the weldable seam relative to a reference point associated with the welding tool; and
generate motion parameters for the welding tool to move the welding tool near the identified position of the weldable seam.

14. The welding robotic system of claim 13, wherein the camera includes a stereoscopic camera, the stereoscopic camera including a first camera and a second camera arranged in a stereo configuration.

15. The welding robotic system of claim 14, wherein:
the images include a first image captured by the first camera and a second image captured by the second camera; and
the first image and the second image are captured relative to a frame of reference of the stereoscopic camera.

16. The welding robotic system of claim 13, wherein the images are captured relative to a frame of reference of the camera.

17. The welding robotic system of claim 16, further comprising:
a positioner positioned in the workspace and including one or more fixture clamps configured to hold the first and second objects in a desired arrangement; and
wherein:
triangulation of the differentiated weldable seam is performed relative to the frame of reference of the camera; and
the position of the weldable seam is identified relative to a frame of reference associated with a positioner device.

18. The welding robotic system of claim 17, wherein the frame of reference of the camera is different from the frame of reference associated with the positioner device.

19. The welding robotic system of claim 17, wherein the robot controller is configured to:
triangulate the differentiated weldable seam to generate one or more three-dimensional (3D) representations of the weldable seam;
determining, based on the one or more 3D representations, gap information along at least a portion of the weldable seam; and
generating welding instructions for the welding tool based on the gap information.

20. The welding robotic system of claim 19, wherein the 3D representations are generated relative to the frame of reference associated with the positioner device.

21. A method of generating instructions for a welding robotic system by a robot controller of a welding robot, the method comprising:
receiving a computer aided design (CAD) model including a representation a first object and a second object associated with a weldable seam;
determining, based on the CAD model, one or more light source parameters for controlling a light source,
controlling the light source to emit light at, the first and second objects positioned to form the weldable seam, wherein controlling the light source comprises controlling one or more light source parameters including an angle of incidence of the emitted light relative to the first object, the second object, or a combination thereof;
during illumination of the first object, the second object, or a combination thereof by the light source, controlling one or more cameras to capture images of the first and second objects along a length of the weldable seam; and
performing segmentation on the images to identify the weldable seam.

22. The method of claim 21, wherein the one or more light source parameters include at least one of:
a pose of the light source selected from a range of poses;
a wavelength of the emitted light;
a luminosity of the emitted light;
a pattern of the emitted light; or
a duration of the emitted light.

23. The method of claim 21, further comprising determining one or more imaging parameters associated with the one or more cameras, the one or more imaging parameters determined based on the CAD model, the one or more light source parameters, or a combination thereof.

24. The method of claim 23, further comprising determining one or more imaging parameters associated with the one or more cameras, the one or more imaging parameters including a camera pose, an aperture size, a focal length, an exposure time, or a combination thereof.

25. The method of claim 21, further comprising:
determining, based on the CAD model, a surface location of a surface the first object or the second object, a seam location of the weldable seam, or a combination thereof; and
wherein the one or more light source parameters are determined based on the surface location, the seam location, or a combination thereof such that the light emitted by the light source is substantially perpendicular to the surface, is aligned with a seam normal line associated with the weldable seam, or a combination thereof.

26. The method of claim 21, further comprising:
identifying multiple waypoints along the weldable seam based on a 3D representation of the weldable seam, the multiple waypoints including a set of points; or
controlling one or more cameras to capture images of the first and second objects along at least a portion of the length of the weldable seam, the portion associated with the set of points.

27. The method of claim 21, wherein performing the segmentation on the images includes differentiating, within the images, the weldable seam from the first and second objects.

28. The method of claim 27, further comprising:
triangulating the differentiated weldable seam to identify a position of the weldable seam relative to a reference point associated with a welding tool coupled to the welding robot; and
generating motion parameters for the welding tool to move the welding tool near the identified position of the weldable seam.

29. The method of claim 27, further comprising:
triangulating the differentiated weldable seam to generate one or more three-dimensional (3D) representations of the weldable seam;
determining, based on the one or more 3D representations, gap information along at least a portion of the weldable seam; and
generating, based on the gap information, welding instructions for a welding tool coupled to the welding robot.

30. The method of claim 29, wherein:
determining the gap information includes:
determining a gap size at a set of points along at least a portion of the length of the weldable seam; and
determining gap variability in gap sizes at the set of points; and
generating welding instructions include generating the welding instructions based on the determined gap variability.
